(19) United States
(12) Patent Application Publication
(10) Pub. No.: US 2024/0304080 A1
(43) Pub. Date: Sep. 12, 2024

(54) CONTROL APPARATUS, SUPERVISORY APPARATUS, CONTROL METHOD AND PROGRAM THEREOF

(71) Applicant: DENSO CORPORATION, Kariya-city (JP)

(72) Inventors: Shogo SHIGEMORI, Kariya-city (JP); Takeshi IIDA, Kariya-city (JP); Tatsuhiro NUMATA, Kariya-city (JP); Tetsuya WATANABE, Kariya-city (JP); Hironori TSUCHIYA, Kariya-city (JP); Takuya HARADA, Kariya-city (JP); Kenji YAMADA, Kariya-city (JP)

(73) Assignee: DENSO CORPORATION, Kariya-city (JP)

(21) Appl. No.: 18/600,893

(22) Filed: Mar. 11, 2024

(30) Foreign Application Priority Data
Mar. 9, 2023 (JP) 2023-036662

(51) Int. Cl. G08C 17/02; G01R 31/3835

(52) U.S. Cl. CPC G08C 17/02; G01R 31/3835

(57) ABSTRACT

A control apparatus performing a wireless communication with a supervisory apparatus that acquires battery information indicating a battery state and transmits the acquired battery information, and controlling the supervisory apparatus based on the battery information. The control apparatus includes a wireless communication unit that wirelessly transmits a plurality of commands which are combined to the supervisory apparatus corresponding to a control period set for a control of monitoring the battery state.

### CROSS-REFERENCE TO RELATED APPLICATION

This application is based on and claims the benefit of priority from earlier Japanese Patent Application No. 2023-036662 filed Mar. 9, 2023, the description of which is incorporated herein by reference.

### BACKGROUND

### Technical Field

The present disclosure relates to a control apparatus, a supervisory apparatus, a control method and a program thereof.

### Description of the Related Art

For example, vehicles such as a hybrid vehicle (HV), a plugin hybrid vehicle (PHV), an electric vehicle (EV) are provided with a battery assembly composed of lithium-ion batteries for vehicle travelling for example. The battery assembly refers to a configuration in which battery cells are combined. A supervisory circuit is provided to monitor the state of respective battery cells.

In the case where a battery management system (BMS) is configured such that a mounted portion of the supervisory circuit is a satellite type, a supervisory circuit is mounted on a supervisory apparatus, a control apparatus communicates with a satellite battery module by a wireless communication unit, and the supervisory circuit mounted on the supervisory apparatus acquires voltage information of the battery cells in accordance with a command transmitted from the control apparatus.

### SUMMARY

The wireless communication unit of the control apparatus according to a first aspect of the present disclosure acquires battery information including information indicating the battery state, wirelessly communicates with a supervisory apparatus which transmits the battery information, thereby controlling the supervisory apparatus based on the battery information. The control apparatus wirelessly transmits a plurality of commands being integrated, corresponding to a control period set for monitoring the battery state.

Thus, the control apparatus is able to communicate to acquire the battery information acquired by the battery supervisory apparatus at a suitable timing. Further, a plurality of commands are integrated and transmitted at the same time in accordance with a control period used for controlling the functions related to the battery supervisory processes. Hence, the control apparatus is able to issue commands for monitoring the battery state at every control period.

### BRIEF DESCRIPTION OF THE DRAWINGS

In the accompanying drawings:

FIG. 1 is a block diagram roughly showing a battery supervisory system according to a first embodiment of the present disclosure;

FIG. 2 is a perspective view diagram schematically showing a structure of a battery pack;

FIG. 3 is a side view diagram schematically showing a structure of the battery pack;

FIG. 4 is a plan view diagram schematically showing a structure of the battery pack;

FIG. 5 is diagram showing an electrical configuration of the battery supervisory system;

FIG. 6 is a sequence diagram roughly showing communication process flow between a supervisory apparatus and a control apparatus;

FIG. 7 is a table explaining commands included in a command set and a control period;

FIG. 8 is a diagram showing a technical advantage of embodiments of the present disclosure when compared with a comparative example;

FIG. 9 is a sequence diagram showing overview of a communication process flow between a supervisory apparatus and a control apparatus according to a second embodiment;

FIG. 10 is a flowchart showing overview of processes executed by a supervisory apparatus according to a third embodiment;

FIG. 11 is a flowchart showing overview of processes executed by a supervisory apparatus according to a fourth embodiment;

FIG. 12 is a flowchart showing overview of processes executed by a supervisory apparatus according to a fifth embodiment;

FIG. 13 is a flowchart showing overview of processes executed by a supervisory apparatus according to a sixth embodiment;

FIG. 14 is a perspective view diagram schematically showing a battery pack according to a seventh embodiment

FIG. 15 is a perspective view diagram schematically showing a structure of a battery pack according to an eighth embodiment; and

FIG. 16 is a perspective view diagram schematically showing a structure of a battery pack according to a ninth embodiment.

### DETAILED DESCRIPTION OF THE PREFERRED EMBODIMENTS

For example, vehicles such as a hybrid vehicle (HV), a plugin hybrid vehicle (PHV), an electric vehicle (EV) are provided with a battery assembly composed of lithium-ion batteries for vehicle travelling for example. The battery assembly refers to a configuration in which battery cells are combined. A supervisory circuit is provided to monitor the state of respective battery cells.

In the case where a battery management system (BMS) is configured such that a mounted portion of the supervisory circuit is a satellite type, a supervisory circuit is mounted on a supervisory apparatus, a control apparatus communicates with a satellite battery module by a wireless communication unit, and the supervisory circuit mounted on the supervisory apparatus acquires voltage information of the battery cells in accordance with a command transmitted from the control apparatus. As an example, according to a configuration disclosed by Japanese Patent Application Laid-Open Publication No. 2019-221050, a master device and a slave device are present corresponding to a control apparatus and a supervisory apparatus respectively. The master device transmits a plurality of commands to the slave device at the same time in a period corresponding to a time interval required for the slave device to process a task, sequentially executes the plurality of processes related to the task and returns the measurement result as a response for each task. For example, with a slave side task #1, a plurality of processes are executed and the measurement result thereof are transmitted to the master device as the response.

According to the technique disclosed by the above-described patent literature, in the case where the master device fails to receive the response data of respective tasks in the middle of the process before completing the control period for controlling functions related to the battery monitoring, the response data of the tasks accumulated in the master side becomes invalid data. In this respect, a control apparatus is preferably be configured to command a supervisory apparatus to transmit the state of the battery at each control period used for controlling the functions related to the battery supervisory apparatus.

Hereinafter, with reference to the drawings, some of the embodiments of a supervisory apparatus and a control apparatus will be described. In the embodiments described below, for the same or similar configurations in the respective embodiments, the same or similar symbols are applied and the description thereof may be omitted.

### First Embodiment

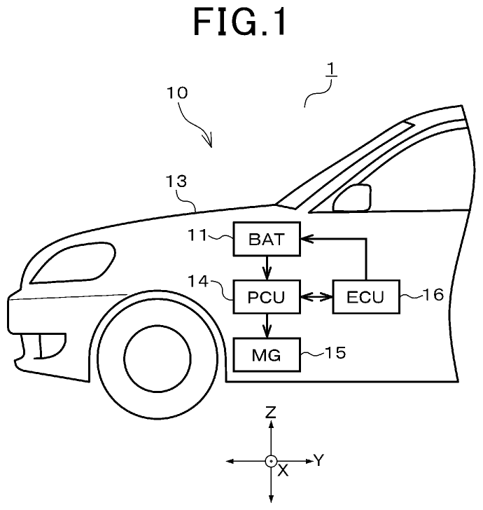

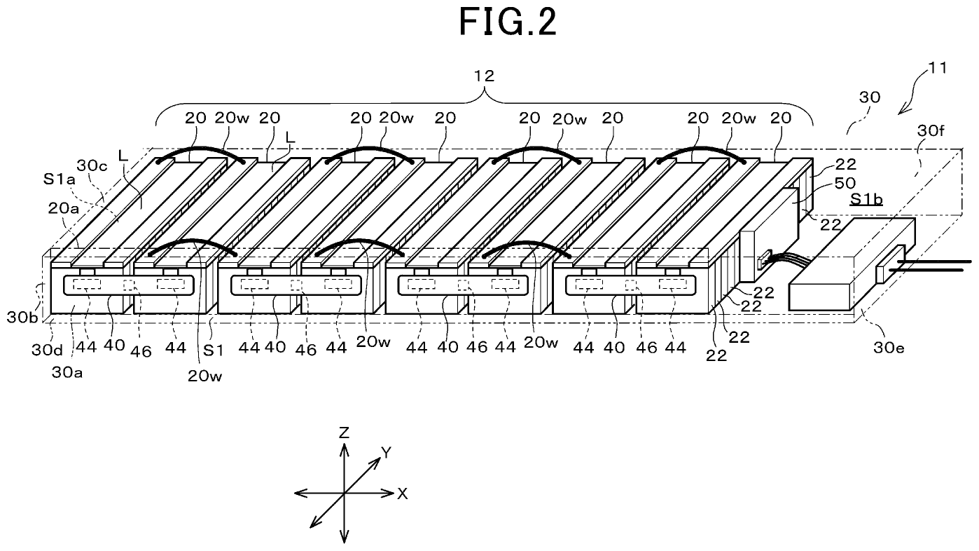

With reference to FIGS. 1 to 6, a first embodiment will be described. As shown in FIG. 1, a battery supervisory system 1 is configured mainly of a battery pack system 2 and installed in a vehicle 10. The vehicle 10 may be a hybrid vehicle (HV), a plug-in hybrid vehicle (PHV) or an electric vehicle (EV). The vehicle 10 travels with a battery assembly 12 (see FIG. 2) of a battery pack 11 mounted thereon as at least a part of a driving source.

In a vehicle 13, the battery pack 11, a power control unit (hereinafter referred to PCU) 14, a motor 15 and a host ECU 16 are mounted. The host ECU 16 is configured as an electronic control apparatus. The battery pack 11 may be installed in an engine compartment or may be installed under a seat of the passenger, for example, under the driver's seat, in a vicinity of a frame of the vehicle body 13 or in a trunk compartment.

As shown in FIG. 2, the battery pack 11 is provided with a battery module 20 in which battery cells 22 are formed in a plurality of groups. Also, a plurality of groups of battery pack 11 are provided. In the battery module 20, plenty of battery cells 22 are accommodated so as to configure a battery assembly 12. In the battery assembly 12, a driving power of the motor 15 is accumulated which is utilized for a driving force of the vehicle 10. The PCU 14 shown in FIG. 1 supplies the power accumulated in the battery assembly 12 of the battery pack 11 to the motor 15. The motor 15 returns the regenerative power to the battery assembly 12 when the vehicle is stopping by a braking operation, and the battery assembly 12 of the battery pack 11 is charged depending on the power generated by the motor 15.

A structure of the battery pack 11 will be described. An example of the structure of the battery pack 11 will be described with reference to FIGS. 2 to 4. In FIG. 2, an inner wall of a housing 30 is indicated by a two-dot chain line. For the housing 30, the longitudinal direction thereof is defined as a X direction and a short side direction thereof is defined as a Y direction. Also, a vertical direction which is orthogonal to a mounted surface of the vehicle 13 is defined as Z direction. The X direction, Y direction and Z direction cross with each other (e.g. orthogonally cross). The housing 30 includes a first wall surface 30a along the X direction and a second wall surface 30b along the Y direction. The housing 30 is formed in a rectangular box shape of a thin-flat type, a flat-type and a low-height type.

As shown in FIG. 2, the housing 30 accommodates the battery assembly 12, a plurality of supervisory apparatuses 40 and a control apparatus 50 in a plane direction along the X direction and the Y direction. The supervisory apparatus 40 corresponds to a battery supervisory apparatus and a battery supervisory apparatus body. The supervisory apparatus 40 includes a supervisory circuit that monitors the battery pack 11 and is referred to as a satellite battery module (i.e. SBM).

The lower surface of the housing 30 with respect to the Z direction serves as a mounted surface. According to the present embodiment, the X direction is a left-right direction of the vehicle and the Y direction is a longitudinal direction of the vehicle 10, and the Z direction is a vertical direction of the vehicle 10. Note that arrangement shown in FIGS. 2 to 4 is an example. A direction with which the housing 30 is mounted to the vehicle body 13 is an example and the battery pack 11 may be arbitrarily arranged to the vehicle 10.

The battery assembly 12 includes a plurality of battery modules 20 arranged in parallel in the X direction. The plurality of battery modules 20 are arranged in the X direction. The battery modules 30 may be referred to as a battery stack or a battery block. The battery assembly 12 may be configured such that a plurality of battery modules 20 are connected in series or parallel. However, according to the present embodiment, it is exemplified that a plurality of battery modules 20 are connected in series.

Each battery module 20 is provided with a plurality of battery cells 22 each formed in a rectangular box shape. In other words, the battery module 20 is configured to have a plurality of battery cells 22 as a group. Each battery module 20 is arranged such that the plurality of battery cells 22 are arranged in the Y direction. Each battery cell 22 is accommodated in a battery case which is not shown, thereby fixing relative positions between the plurality of battery cells 22. The battery case is made of a metal or a resin. When the battery case is made of metal and formed in a rectangular box shape, an electrical-insulation material is interposed between the wall surface of the battery case and the battery cell 22. The insulation material may be partially interposed between the wall surface of the battery case and the battery cell 22.

The battery module 20 includes a plurality of battery cells 22 connected in series. The battery module 20 according to the present embodiment is configured such that a plurality of battery cells 22 arranged in the Y direction are connected in series. The battery assembly 12 provides a DC power source.

The battery cell 22 serves as a secondary battery that generates an electromotive force with a chemical reaction. As the secondary battery, a lithium-ion secondary battery, a nickel-hydrogen secondary battery, an organic radical battery or the like may be utilized. The lithium-ion battery is a secondary battery in which lithium serves as charge carrier. The secondary batteries which can be utilized for the battery cell 22 may include so-called all-solid-state batteries which utilize solid electrolyte other than secondary batteries of which the electrolyte is liquid type.

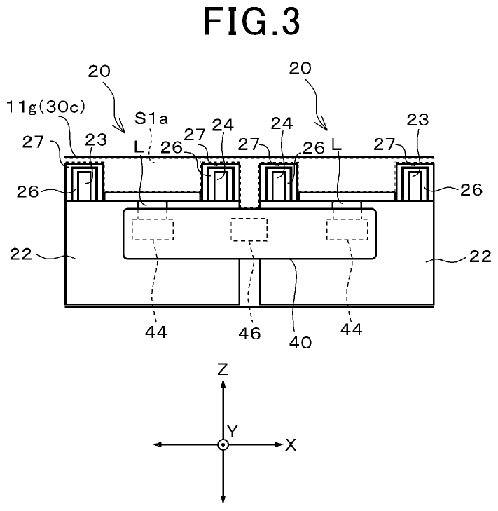

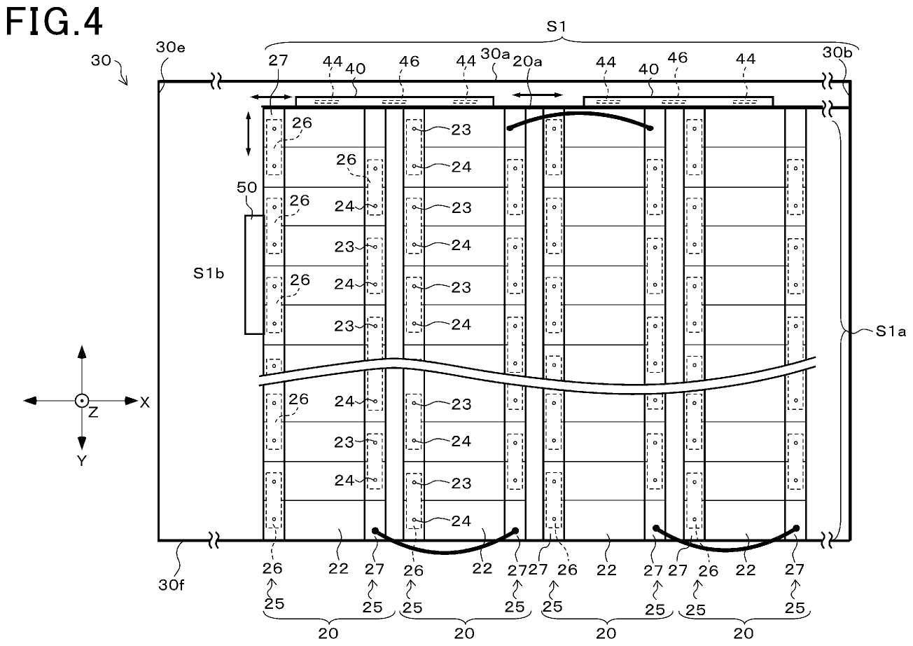

As shown in FIGS. 2 to 4, respective battery cells 22 are laminated such that side surfaces of the battery case are touched with each other. The battery cell 22 is provided with a positive electrode terminal 23 and a negative electrode terminal 24 positioned at both ends in the X direction, protruding in the Z direction, that is, Z+ direction indicating upward direction. As shown in FIG. 3, the positive electrode terminal 23 and the negative electrode terminal 24 are arranged such that positions of protruded end faces of the positive and negative electrodes 23, 24 have the same height in the Z direction between respective battery cells 22. As shown in FIG. 4, the respective battery cells 22 are laminated such that the positive electrode terminal 23 and the negative electrode terminal 24 are alternately arranged in the Y direction.

As shown in FIG. 4, a pair of bus bar units 25 having linear shape are arranged on an upper surface of each battery module 20 at both ends thereof in the X direction. The bus bar units 25 is provided on the end face of each battery module 20 at both ends thereof in the X direction from which the positive and negative electrodes 23 and 24 of the plurality of battery cases protrude.

As shown in FIGS. 3 and 4, each bus bar unit 25 includes a plurality of bus bars 26 electrically connecting the positive electrode terminal 23 and the negative electrode terminal 24 alternately arranged in the Y direction and a bus bar cover 27 that covers the plurality of bus bars 26. The bus bar 26 is a plate-like member made of metal having favorable conductivity such as copper and aluminum. The bus bar 26 electrically connects the positive electrode terminal 23 and the positive electrode 24 of the battery cells 22 adjacently positioned in the Y direction. Thus, the plurality of battery cells 22 are connected in series in each battery module 20.

Each battery module 20 is configured such that a plurality of battery cells 22 are arranged in the Y direction. As shown in FIGS. 3 and 4, the bus bar cover 27 is provided along the Y direction so as to cover the positive electrodes 23 and the negative electrode terminal 24 of the plurality of battery cells 22 in each battery module 20. As shown in FIG. 3, the bus bar cover 27 is provided at both ends of the battery cell 22 in the X direction, protruding upwardly from the upper surface of the battery cell 22. A space S1a is provided to be surrounded by a ceiling surface 11g of the battery pack 11, that is an upper inner surface 30c of the housing 30, an inner side surface of the bus bar cover 27 and an upper surface of the battery cell 22. The space S1a is positioned in a lower side of the upper inner surface 30c of the housing 3, being communicated in the X direction. The space S1a is provided as a propagation path of electromagnetic waves.

Here, with reference to FIG. 4, an electrical connection state of the battery module 20 will be described. In a battery module 20, one end portion of a first battery cell 22 in the X direction is defined as a positive electrode and the other end portion is defined as a negative electrode. At the positive electrode of the battery cell 22, a positive electrode terminal 23 is connected, and at the negative electrode of the battery cell 22, a negative electrode terminal 24 is connected. The second battery cell 22 is provided being positioned at a side portion of the first battery cell 22 in the Y direction. The second battery cell 22 is arranged such that the positions of the positive electrode and the negative electrode in the X direction are positioned inversely compared to that of the first battery cell 22. The bus bar 26 connects between the negative electrode 24 of the first battery cell 22 and the positive electrode 23 of the second battery cell 22.

Further, a third battery cell 22 is provided being positioned at a side portion of the second battery cell 22 in the Y direction.

The third battery cell 22 is arranged such that the positions of the positive electrode and the negative electrode in the X direction are positioned inversely compared to that of the second battery cell 22. The bus bar 26 connects between the negative electrode 24 of the second battery cell 22 and the positive electrode 23 of the third battery cell 22. Thus, a plurality of battery cells 22 are arranged in the Y direction such that the position of the positive electrode and the position of the negative electrode in the X direction are changed. The positive electrode terminal 23 and the negative electrode terminal 24 are connected by the bus bar 26. With this configuration, the battery cells 22 of respective battery modules 20 are electrically connected in series.

In the respective battery modules 20, one battery cell 22 between two battery cells 22 positioned at the end portions of the plurality of battery cells 33 arranged in the Y direction has the maximum potential and the other battery cell 22 has the minimum potential. A wire 20w shown in FIG. 2 is connected to at least one of the positive electrode terminal 23 of the battery cell 22 having the maximum potential and the negative electrode terminal 24 of the battery cell having the minimum potential.

As shown in FIGS. 2 to 4, the positive electrode terminal 23 of one battery cell 22 having the maximum potential between two battery modules 20 adjacently positioned in the X direction and the negative electrode terminal 24 of the other battery cell 22 having the minimum potential are connected via the wire 20w. Thus, a plurality of battery modules 20 are electrically connected in series.

One battery module 20 between two battery modules 20 positioned at end portions of the plurality of battery modules 20 arranged in the X direction is the maximum potential side, and the other battery module 20 is the minimum potential side. In the maximum potential side battery module 20, an output terminal is connected to a positive electrode terminal 23 of the battery cell 22 having the maximum potential between the plurality of battery cells 22.

In the minimum potential side battery module 20, an output terminal is connected to a negative electrode terminal 24 of the battery cell 22 having the lowest potential between the plurality of battery cells 22.

These two output terminals are connected to electrical equipment such as the PCU 12 mounted on the vehicle 10. At least part of the positive electrode terminal 23 and the negative electrode terminal 24 may oppose each other or may not oppose each other.

Note that two battery modules 20 adjacently positioned in the X direction may not be electrically connected via the wire 20w, but any two of a plurality of battery modules 20 may be electrically connected via the wire 20w.

The bus bar cover 27 shown in FIGS. 3 and 4 is formed using an electrical insulation material such as a resin. The bus bar cover 27 is linearly provided from an end to an end of the battery module 20 in the Y direction so as to cover a plurality of bus bars 26. The bus bar cover 27 may include a partition wall. The partition wall is provided, thereby improving insulation properties between two bus bars 26 adjacently positioned in the Y direction.

As shown in FIG. 2, one supervisory apparatus 40 is provided for two adjacently positioned battery modules 20 in the X direction between a plurality of battery modules 20. Here, it is exemplified that one supervisory apparatus 40 is provided for a pair of battery modules 20. However, one supervisory apparatus 40 may be provided for each one battery module 20 or one supervisory apparatus 40 may be provided for three or more battery modules 20.

The supervisory apparatus 40 is provided in an inner side of the first wall surface 30a of the housing 30 to be along a direction (X direction) with which the first wall surface 30a extends, and arranged across the two battery modules 20 in the X direction. A plurality of supervisory apparatuses 40 are each disposed at one end in the Y direction of each battery module 20 and parallelly arranged in the X direction. The supervisory apparatus 40 is provided in an inner side of the first wall surface 30a along the X direction of the housing 30. A plurality of supervisory apparatuses 40 are arranged at the same position with respect to the Y direction.

According to the structure shown in FIG. 2, a plurality of supervisory apparatuses 40 are parallelly arranged at one ends in the Y direction of the battery modules 20. However, it is not limited to this structure. For example, a plurality of supervisory apparatuses 40 may be alternately arranged at one end and the other end in the Y direction for each two battery modules 20 or may not be alternately arranged regularly (may be irregularly alternately arranged).

The supervisory apparatus 40 is embedded to a cavity provided in the battery module 20 for example, and fixed to the cavity by a screw or the like. The fixing method of the supervisory circuit 40 is not limited to this method. For example, the supervisory circuit 40 may be fixed to the battery module 20 using a thermal caulking in which a bonding and a crimping are performed by pressurizing while being heated. Further, with a snap fit connecting structure using an elastic deformation of a metal or a resin material, the supervisory apparatus 40 may be fixed to the battery module 20.

The supervisory apparatus 40 is arranged to have an external dimension thereof which satisfies a relationship of X direction >Z direction >Y direction when being attached to the battery module 20. A space S1 is provided in the vicinity of the supervisory apparatus 40. The space S1 is a space partially surrounded by the first wall surface 30a and the second surface 30b of the housing 30 and the wall surface 20a of the battery module 20. For the supervisory apparatus 40, a thickness in the Y direction among XYZ directions is formed to be the thinnest. Even in the case where the battery module 20 is configured such that a plurality of battery cells 22 are arranged in the Y direction and widely configured in the Y direction, the supervisory apparatus 40 can be disposed in the space of which the dimension in the Y direction is the minimum. Thus, the space S1 in the inner side of the first wall surface 30a of the housing 30 can be effectively utilized.

The supervisory apparatus 40 may preferably be disposed on the wall surface 20a of the battery module 20 closer to an upper portion than a lower portion or a middle portion with respect to the Z direction. Note that when most of the part of the supervisory apparatus 40 is arranged in the upper portion upper than the middle height portion of the battery cell 22, the other part may be arranged in the lower portion than the middle height portion. In other words, the supervisory apparatus 40 may be provided such that a region arranged in the upper portion upper than the middle height portion of the battery cell 22 is larger than a region arranged in the lower portion. In this regard, for example, the supervisory apparatus 40 can readily be arranged from the upper side, whereby the supervisory apparatus 40 may readily be assembled to the battery module 20.

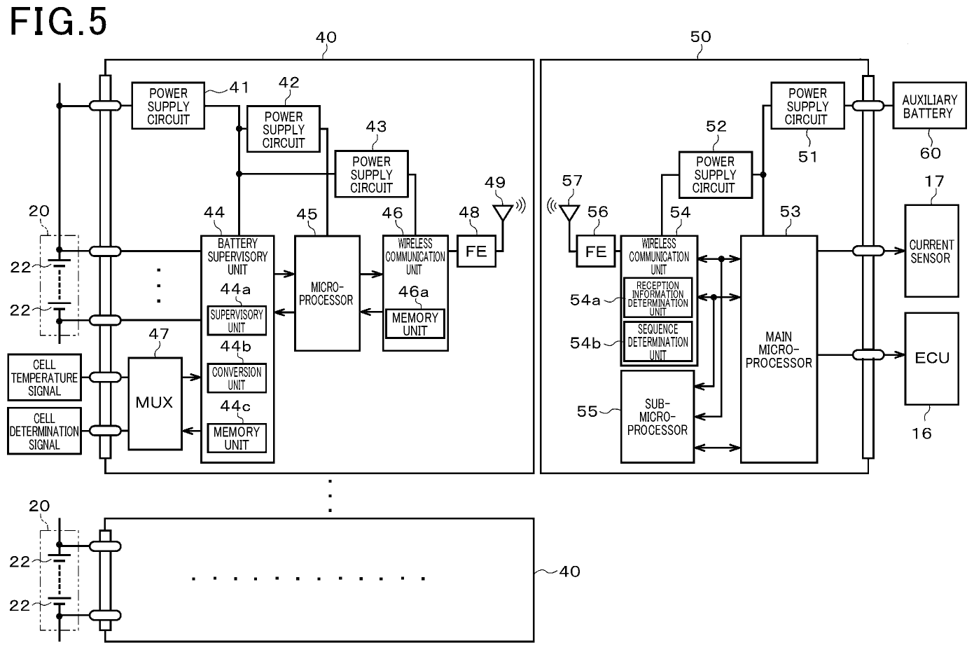

As shown in FIG. 2, the control apparatus 50 is attached to a battery module 20 (i.e. control apparatus side battery module) positioned at the end portion in the X direction of the among all battery modules 20. Specifically, the control apparatus 50 is attached to an outer end face of the control apparatus side battery module in the X direction. As shown in FIG. 5, the supervisory apparatus 40 is provided with an antenna 49 and the control apparatus 50 is provided with an antenna 57. The control apparatus 50 is connected to the plurality of supervisory apparatuses 40 via a wireless communication.

As described, the control apparatus 50 and the supervisory apparatuses 40 are connected via wireless communication. Assuming that the control apparatus 50 and the supervisory apparatuses are wired-connected, harnesses are required to connect the control apparatus 50 and the supervisory apparatuses 40 with each other. For example, in the case where an operator extends a harness into the space S1 at inner side of the first wall 30a of the housing 30 to connect between the supervisory apparatus 40 and the control apparatus 50, the efficiency of assembling the battery assembly 12 will be lowered, requiring many work-hours. In this respect, according to the present disclosure, since the supervisory apparatuses 40 and the control apparatus 50 are connected via a wireless communication, the supervisory apparatuses can be arranged in the minimized space S1 without lowering the efficiency of assembly of the battery assembly 12.

Note that a fixing member for fixing the supervisory apparatus 40 to the battery module 20 may be non-magnetic material. With this configuration, the performance of wireless communication can be improved. For the components used for the battery module 20, non-magnetic material may be utilized when magnetic properties are not required.

Each supervisory apparatus 40 is fixed to one end face of the battery module 20 in the Y direction. As shown in FIGS. 2 and 3, a detection line L is connected to the supervisory apparatus 40. The detection line L is provided for each battery module 20. The detection line L extends upwardly from an upper portion of the supervisory apparatus 40 and is bent at an end portion of the battery module 20 to extend in the Y direction on the upper portions of the plurality of battery cells 22. The detection line L indicates a harness for detecting a voltage between the positive electrode terminal 23 and the negative electrode terminal 24 of each battery cell 22.

The detection line L is configured to extend in the Y direction along the upper surfaces of the plurality of battery cells 22 that constitute one battery module 20.

The detection line L is disposed between bus bar covers 27 provided at both ends in the X direction of each battery cell 22. The detection line L includes a core wire (not shown) extending to both sides of the battery cells 22 in the X direction to be electrically connected to the positive electrode 23 and the negative electrode 24 of each battery cell 22.

Structure of the housing 30 will be described.

The housing 30 has properties of reflecting electromagnetic waves for a countermeasure of electromagnetic compatibility (EMC). The housing 30 is configured to include a resin material and a metal having magnetic properties for reflecting electromagnetic waves, that is, magnetic material. The housing 30 may include a resin material, but the magnetic material may cover the resin material, or may be embedded inside the resin material. The housing 30 may be configured of a resin material but may be covered by the chassis of the vehicle 10 for an EMC countermeasure. The housing 30 may be configured to include carbon fiber. The housing 30 may be configured to include a material having properties of absorbing electromagnetic waves instead of properties of reflecting electromagnetic waves.

The first wall surface 20a positioned at one end in the Y direction of the plurality of battery modules 20 (see FIGS. 2 and 4) are formed in the X direction. The wall surface 20a may be covered by a reflection member (e.g. metal having magnetic properties or a magnetic material) for reflecting electromagnetic waves. For the space S1 positioned at an inner side of the first wall surface 30a of the housing 30, for example, dimensions in a YZ plane (vertical-horizontal direction) are several millimeters (mm) to several centimeters (cm) or several tens of centimeters (cm).

As described above, a part of the space S1 is surrounded by the wall surface 20a of the battery module 20, the first wall surface 30a, a lower inner surface 30d, a upper inner surface 30c and the second wall surface 30b. The space S1 is partially closed by a metal as a reflection member and opened at a space S1b side positioned in one side in the X direction where the control apparatus 50 is disposed (i.e. wall surface 30e side in the left side shown in FIG. 4).

The plurality of supervisory apparatuses 40 are periodically arranged in the X direction at the same intervals in the space S1. As long as the space S1 is covered by a metal, the space S1 constitutes a waveguide tube similar to a so-called rectangular wave guide. As shown in FIG. 4, the housing 30 constitutes a space closed by the first wall surface 30a, the second wall surface 30b, the third wall surface 30f and the fourth wall surface 30f in plan view.

The first wall surface 30a faces the fourth wall surface 30f, and the second wall surface 30b faces the third wall surface 30e. At this moment, the propagation space allowing electromagnetic waves to propagate when wireless communication is performed between the control apparatus 50 and the supervisory apparatus 40 is formed in an L-shape in plan view. The electromagnetic waves emitted by the control apparatus 50 are reflected at the first wall surface 30a and propagated to the space S1, and also reflected at the third wall surface 30e and propagated to the space S1 to reach the supervisory apparatus 40.

The electromagnetic waves emitted by the supervisory apparatus 40 are propagated in the space S1 and reflected at the first wall surface 30a to reach the control apparatus 50, and also propagated in the space S1 and reflected at the third wall surface 30e to reach the control apparatus 50. Thus, wireless communication is performed between the control apparatus 50 and the supervisory apparatus 40, whereby electromagnetic waves are propagated through the L-shaped propagation path including the space S1.

According to the present embodiment, the propagation path in which the electromagnetic waves are propagated when wireless communication is performed between the control apparatus 50 and the supervisory apparatus 40 includes the space S1a. The space S1a is positioned between the bus bar covers 27 disposed at both ends in the X direction of the battery cell 22 and surrounded by the ceiling surface 11g, that is, the upper inner surface 30c of the housing 30 and the upper surface of the battery cell 22. The space S1a is provided to include a gap below the upper inner surface 30c of the housing 30.

The space S1a is provided being communicated towards the X direction along a lower side of the upper inner surface 30c of the housing 30.

The space S1a is communicated in the X direction to a space S1b where the control apparatus 50 is provided. Thus, the space S1a, S1b can be used as propagation paths of electromagnetic waves for a wireless communication between the control apparatus 50 and the supervisory apparatus 40. Hence, communication paths can be further provided in addition to the above-described L-shaped propagation path.

The housing 30 is provided with holes for communicating with an accommodation space of the battery pack 11 and its outside space. The holes are used as an air communication hole, or for a power line to pass therethrough or used for leading signal lines therethrough. With a configuration having holes, a covering part (not shown) that covers holes may be provided. For example, the covering part is configured of a connector, an electromagnetic shielding member, a sealing material and the like. The covering part closes a part of or all of holes between the accommodation space of the battery pack 11 and its outside space.

The covering part is configured to include a metal material having magnetic characteristics. The covering part may include a resin material. The magnetic material may be configured to cover the resin material or may be embedded in the resin material. The covering part may be configured to include carbon fiber.

The holes of the housing 30 may be covered by any elements accommodated in the accommodation space of the housing 30 without having the covering part. Moreover, the power line or the signal lines may be disposed between the accommodation space and the outside space while being supported by an electrical insulation member constituting a part of the wall part of the housing 30.

Modification example of arrangement of a plurality of supervisory apparatuses 40 and the control apparatus 50 will be described. Note that a structure of mounting the plurality of supervisory apparatuses 40 and the control apparatus 50 is not limited to the structure shown in FIG. 2. For example, the plurality of supervisory apparatuses 40 may be attached to respective battery modules 20 inside the housing 30, and the control apparatus 40 may be attached to an outside surface of the housing 30.

For example, a mounting structure of may be utilized in which a wall surface of the housing 30 is provided in a facing region between the supervisory apparatus 40 and the control apparatus. In this case, compared to mounting structure shown in FIG. 2, although a propagation environment of electromagnetic waves propagating between the supervisory apparatus 40 and the control apparatus 50 is deteriorated, a communication process between the supervisory apparatus 40 and the control apparatus 50 may still be performed. For example, the wall surface of the housing 30 where the control apparatus 50 is provided may be formed of a resin which allows electromagnetic waves to pass therethrough. Moreover, an opening may be formed on the wall surface of the housing 30 and the control apparatus 50 may be disposed so as to close the opening.

The antenna 49 included in the supervisory apparatus 40 may be disposed not to be overlapped with the bus bar unit 25 in the XY direction. That is, the antenna 49 may be disposed protruding in the Z direction from the bus bar unit 25.

The antenna 57 connected to the control apparatus 50 may be disposed at a Z-direction height similar to that of the antenna 49 of the supervisory apparatus 40. Note that a relationship of dispositions between the antennas 49 and 57 is not limited to the above dispositions.

Hereinafter, modification examples of arrangement structure of the battery module 20 will be described.

According to the present embodiment, it is exemplified that a plurality of battery modules 20 each having a plurality of battery cells 22 packed therein are prepared and directly accommodated in the housing 30. However, a structure of so-called non-module batteries may be utilized. For example, a structure of Cell to Pack (CTP) may be utilized in which the plurality of battery cells 22 are not arranged in a battery module but the plurality of battery cells are directly accommodated in the battery pack 11.

Further, a structure of battery Module to Platform (MTP) may be utilized in which the battery module 20 may be directly mounted to a frame, a platform of the vehicle 10. Furthermore, a structure of Cell to Chassis (CTC) may be utilized in which the battery cells 22 are directly packed on the chassis of the vehicle 10 and a part of the battery cells 22 are attached in the chassis as a part of the body structure.

Hereinafter, configurations of PCU 14, motor 15 and host ECU 16 will be described. The host ECU 16 and the control apparatus 50 may be configured such that a part of or all of configurations thereof are integrated or may be configured separately. The PCU 14 shown in FIG. 1 executes a bi-directional power conversion between the battery pack 11 and the motor 15. The PCU 14 is configured to include an inverter that drives the motor 15 and a boost-converter that boosts the DC voltage supplied to the inverter to be higher than or equal to the output voltage of the battery pack 11.

The motor 15 is an AC rotary electric machine configured as, for example, a three-phase AC synchronous motor where permanent magnet is embedded in a rotor. The motor 15 is driven by the PCU 14 to generate rotational driving force which is transmitted to driving wheels. On the other hand, when the vehicle 10 is stopping, the motor 15 operates as a generator to perform regenerative generation. The power generated by the motor 15 is supplied to the battery pack 11 via the PCU 14 and stored in the battery assembly 12 of the battery pack 11.

The host ECU 16 is configured including CPU, a memory unit such as ROM, RAM and non-volatile semiconductor memory device, input-output port for receiving or outputting various signals. In the memory unit, programs to be executed by the host ECU 16 are stored therein and the CPU executes the programs stored in the memory unit. The memory unit is utilized as a non-transitory tangible recording media. The control apparatus 50 receives cell voltage information of respective battery cells 22 of the battery assembly 12 from the supervisory apparatuses 40 of the battery pack 11, measures the state of charge (i.e. SOC) and controls the PCU 14, thereby controlling a driving of the motor 15 and a charging-discharging of the battery pack 11.

For the battery assembly 12, a current sensor 17 (see FIG. 5) is connected in series thereto. Thus, current flowing in the whole battery assembly 12 can be measured. As shown in FIG. 5, the current sensor 17 is connected to the control apparatus 50. The host ECU 16 is able to acquire current information detected by the current sensor 17 via the supervisory apparatuses 40 and the control apparatus 50, that is, an amount of current flowing through the battery assembly 12 or the battery cell 22.

Here, it is exemplified an embodiment where the current sensor 17 is connected to the control apparatus 50.

However, the current sensor 17 may be connected to the host ECU 16. Since the control apparatus 50 and the host ECU 16 can be mutually connected for communication, although any of the configurations may acquire the current information of the current sensor 17, the current information of the current flowing through the battery assembly 12 can be shared therebetween.

Hereinafter, electrical configurations of the supervisory apparatus 40, the control apparatus 50 will be described.

Firstly, an electrical configuration of the supervisory apparatus 40 will be described. As shown in FIG. 5, the supervisory apparatus 40 is provided with power source circuits 41 to 43, a battery supervisory unit 44, a microprocessor 45, a wireless communication unit 46, a selection circuit 47, a matching circuit 48 and an antenna 49. The power source circuit 41 of the supervisory apparatus 40 generates an operation voltage using a voltage supplied from the battery module 20, supplies the generated voltage to the power source circuits 42 and 43 and to the battery supervisory unit 44. The power source circuit 42 generates an operation voltage from the output of the power source circuit 41 and supplies the generated voltage to the microprocessor 45. The power source circuit 43 generates an operation voltage from the output of the power source circuit 41 and supplies the generated voltage to the wireless communication unit 46.

The selection circuit 47 of the supervisory apparatus 40 receives, as battery information, a cell temperature signal detected by a temperature sensor (not shown) that measures a temperature of the battery cell 2 and a cell determination signal that determines a type of the battery cell 22, selects the battery information and transmits the selected information to the battery supervisory unit 44. The battery supervisory unit 44 of the supervisory apparatus 40 is composed of one or more battery supervisory ICs used for sensing battery information such as cell voltage of the battery cell 22, a cell temperature and a cell type determination.

The battery supervisory unit 44 is provided with a supervisory unit 44a that acquires battery information of the battery cell 22 of the battery assembly 12, a conversion unit 44b that convers an analog value of the battery information received via the selection circuit 47 to be a digital value, and a memory unit 44c that stores the digital value of the battery information. The supervisory unit 44a is composed of one or more battery supervisory ICs. In the case where the battery supervisory unit 44 is provided with a plurality of battery supervisory ICs, the battery cells 22 are assigned to any one of the battery supervisory ICs in advance which acquires the battery information thereof. The memory unit 44c is configured of registers and the like. The battery supervisory unit 44 causes the memory unit 33c to sequentially store the battery information of battery cells 22. However, the battery information may be removed when it is required in order to secure sufficient memory capacity.

The battery supervisory unit 44 causes the memory unit 46a of the wireless communication unit 46 to store, via the microprocessor 45, the battery information as the battery supervisory information, for example, voltage information of the battery, temperature information of the battery, and battery type determination information of the battery cell 22. The battery supervisory unit 44 executes a failure diagnosis process for a circuit part of the supervisory apparatus 40, monitors its failure diagnosis information and causes the memory unit 46a of the wireless communication unit 46, via the microprocessor 45, to store the failure diagnosis information.

The microprocessor 45 of the supervisory apparatus 40 receives battery supervisory information or failure diagnosis information transmitted from the battery supervisory unit 44 and transmits the received information to the wireless communication unit 46. The microprocessor 45 has a function of controlling an acquisition schedule of the battery supervisory information or the failure diagnosis information of the battery supervisory unit 44.

The wireless communication unit 46 includes the memory unit 46a. The wireless communication unit 46 wirelessly transmits, as wireless communication, the information stored in the memory unit 46a to the wireless communication unit 54 of the control apparatus 50. The wireless communication unit 46 of the supervisory apparatus 40 stores, when receiving the battery supervisory information or the failure diagnosis information from the microprocessor 45, the battery supervisory information or the failure diagnosis information into the memory unit 46a and transmits the information to the control apparatus 50 in the master side. The wireless communication unit 46 transmits the information to the wireless communication unit 54 of the control apparatus 50 and receives the information from the wireless communication unit 54 of the control apparatus 50 at the memory unit 46a. The wireless communication unit 46 serves as a communication device that controls a communication data size, a communication type, a communication schedule, an error detection and the like between the supervisory apparatus 40 and the control apparatus 50.

The matching circuit 48 of the supervisory apparatus 40 and the antenna 49 serves as a physical interface in which the output signal of the wireless communication unit 46 is converted to electromagnetic waves to be emitted in the space and the electromagnetic waves propagated in the space are received to be inputted to the wireless communication unit 46.

The above-described microprocessor 45 may not be provided. Alternatively, the wireless communication unit 46 and the battery supervisory unit 44 may be configured to directly communicate therebetween. The wireless communication unit 46 of the supervisory apparatus 40 may manage an acquisition schedule or a transmission schedule of the battery supervisory information of the battery supervisory unit 44 and the failure diagnosis information.

Specific configuration of the control apparatus 50 will be described.

The control apparatus 50 is provided with power circuits 51 and 52, a main microprocessor 53, a wireless communication unit 54, a sub microprocessor 55, a matching circuit 56 and the antenna 57. The power source circuit 51 of the control apparatus 50 generates an operation voltage using a voltage supplied from an auxiliary battery 60, supplies the operation voltage to the power source circuit 52 and the main microprocessor 53. The power source circuit 52 generates an operation voltage using the output of the power source circuit 51 and supplies the generated operation voltage to the wireless communication unit 54.

The matching circuit 56 of the control apparatus 50 and the antenna 57 serves as a physical interface in which the output signal of the wireless communication unit 54 is converted to electromagnetic waves to be emitted in the space and the electromagnetic waves propagated in the space are received to be inputted to the wireless communication unit 54.

The wireless communication unit 54 of the control apparatus 50 receives the battery supervisory information or the failure diagnosis information as the battery information transmitted from the wireless communication unit 46 of the supervisory apparatus 40 and transmits the information to the main microprocessor 53 of the control apparatus 50. The wireless communication unit 54 in the control apparatus 50 side receives data transmitted from the main microprocessor 53 and transmits the received data to the wireless communication unit 46 of the supervisory apparatus 40. The wireless communication unit 54 serves as a communication device that controls a communication data size, a communication type, a communication schedule, an error detection and the like between the supervisory apparatus 40 and the control apparatus 50.

The main microprocessor 53 of the control apparatus 50 calculates SOC or diagnosis information as a state index of the battery cell 22 using the voltage and the temperature of the battery cell 22 transmitted from the wireless communication unit 46 and transmits the calculated information to the host ECU 16. The main microprocessor 53 controls an ON/OFF state of the ignition switch and switching of the cell balancing process.

The main microprocessor 53 controls the operation state of the supervisory apparatus 40 by wirelessly transmitting information such as a control signal to the supervisory apparatus 40 via the wireless communication units 46 and 54. The sub microprocessor 55 of the control apparatus 50 monitors data being exchanged between the wireless communication unit 54 and the main microprocessor 53, and monitors an operation state of the main microprocessor 53. Also, the sub microprocessor 55 may monitor the operation state of the wireless communication unit 54.

According to the present embodiment, the control apparatus 50 is provided with the sub microprocessor 55 which monitors the data exchanged between the wireless communication unit 54 and the main microprocessor 53 and also monitors the operation state of the main microprocessor 53. However, the configuration of the control apparatus 50 is not limited to such examples. For example, the control apparatus 50 may not be provided with the sub microprocessor 55.

In the case where the microprocessor 45 is not mounted on the supervisory apparatus 40 as described above, the main microprocessor 53 of the control apparatus 50 may manage the battery supervisory information of the battery supervisory unit 44 and an acquisition schedule or a transmission schedule of the failure diagnosis information.

According to the present embodiment, the main microprocessor 53 of the control apparatus 53 is configured to calculate the SOC or the diagnostic information as a state index of the battery cell 22, using the battery information such as a voltage and a temperature of the battery cell 22 transmitted from the wireless communication unit 46 and transmit the calculated information to the host ECU 16. However, the calculation of the battery information is not limited to this example.

For example, the microprocessor 45 of the supervisory apparatus 40 may calculate the SOC or the diagnostic information as a state index of the battery cell 22, using the battery information such as the voltage and the temperature of the battery cell 22 acquired by the battery supervisory unit 44 and transmit the calculation result to the wireless communication unit 54 of the control apparatus 50. In other words, the microprocessor 45 of the supervisory apparatus 40 may perform an abnormality diagnostic process for the battery cell 22 or the battery supervisory unit 44 using the calculation result, and transmit the result of the abnormality diagnostic process to the wireless communication unit 54 of the control apparatus 50.

Also, the voltage, the battery information such as the voltage, the temperature and the like of the battery cell 22 acquired by the battery supervisory unit 44 of the supervisory apparatus 40 may be calculated by the wireless communication unit 46 of the supervisory apparatus 40. Further, the battery information such as the voltage and the temperature of the battery cell 22 acquired by the battery supervisory unit 44 of the supervisory apparatus 40 may be calculated by the wireless communication unit 54 of the control apparatus 50. In other words, the microprocessor 45 of the supervisory apparatus 40 may perform an abnormality diagnostic process of the battery cell 22 using the calculation result and transmit the result of the abnormality diagnostic process as the battery information to the wireless communication unit 54 of the control apparatus 50.

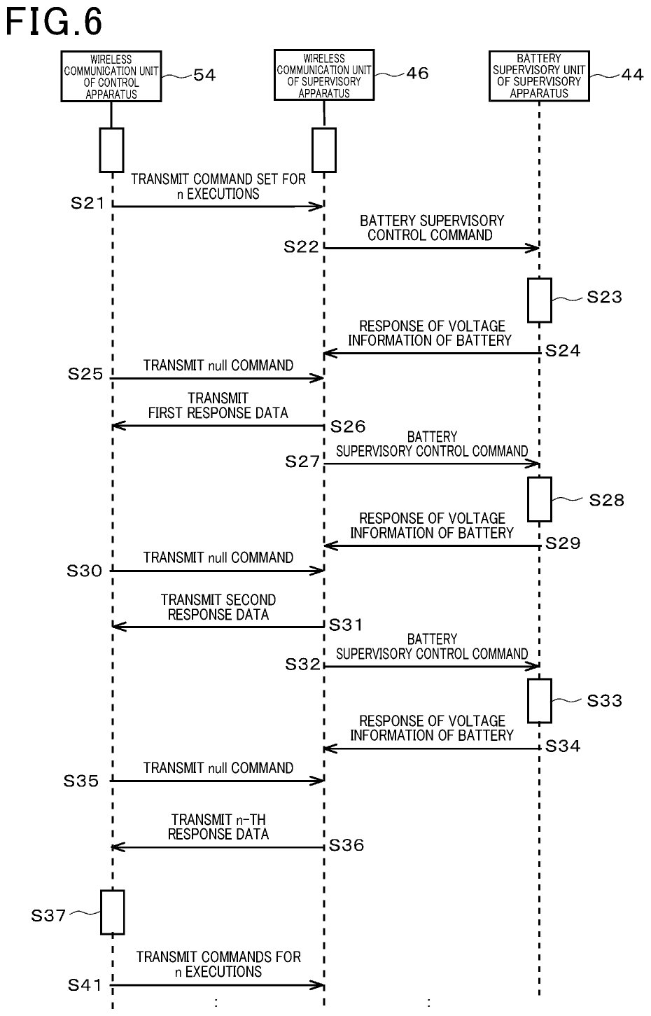

Hereinafter, a wireless communication process will be described. With reference to FIG. 6, a wireless communication process between the supervisory apparatus 40 and the control apparatus 50 will be described. A battery supervisory system 1 according to the present embodiment is configured such that a plurality of supervisory apparatuses 40 are connected as a star-connection network of which the center apparatus is the control apparatus 50. Note that, in the star-connection network, packet communication can be performed.

The control apparatus 50 establishes the communication link with each of the plurality of supervisory apparatuses 40 separately and performs the wireless communication. When activate the vehicle 10, the user operates the ignition switch to be ON state from OFF state, at this moment, the activation signal thereof is applied to the control apparatus 50. When the control apparatus 50 is activated, the control apparatus 50 executes a process for establishing a communication with each of the supervisory apparatuses 40 When a communication establishing process is completed for the supervisory apparatus 40, the control apparatus 50 starts a periodic communication with the supervisory apparatuses 40 with which communication is established and maintains the established communication.

As shown in FIG. 6, in the periodic communication process, the wireless communication unit 54 of the control apparatus 40 transmits, at step S21, a command set included in one or more communication frames, including commands for n command executions (n≥2), to the supervisory apparatus 40. At this moment, the wireless communication unit 54 of the control apparatus 50 transmits a command set to each wireless communication unit 46 in the plurality of supervisory apparatuses 40 using a unicast communication in a time-sharing manner.

The command set integrates a plurality of commands for n command executions and is configured corresponding to a control period which is set for a control of monitoring the state of the battery assembly 12. The main microprocessor 53 of the control apparatus 50 receives response data corresponding to one command set, whereby the state of the battery assembly can be monitored.

The plurality of commands indicates an operation command required for monitoring the battery assembly 12. The operations required for monitoring the battery assembly 12 includes at least one of voltage acquisition of the battery cell 22 of the battery assembly 12, a temperature detection of the battery cell 22 of the battery assembly 12, a failure detection of the battery assembly 12, and an operation for changing the control to the supervisory apparatus 40 required for monitoring the battery assembly 12 with the control apparatus 50.

Among commands for n command executions, a command of one execution includes a command for voltage monitoring of the battery assembly 12 and a control command for failure diagnosis, or a transmission request command of acquired information. The command for voltage monitoring of the battery assembly 12 indicates a command for acquisition request of the battery supervisory information. The control command for failure diagnosis indicates a command for acquisition request of the failure diagnosis information. Also, the transmission request command of the acquired information indicates a request command used for requiring transmitting the acquired information.

Once receiving the commands, the wireless communication unit 46 of the supervisory apparatus 40 issues, at step S22, a battery supervisory control command to the battery supervisory unit 44, for example.

The battery supervisory command includes a command for supervising the battery and a transmission request command, and executes an acquisition request of the battery supervisory information. The wireless communication unit 46 of the supervisory apparatus 40 utilizes the battery supervisory control command to transmit the acquisition request of the battery supervisory information to the battery supervisory unit 44 via the microprocessor 45.

The battery monitoring unit 44, when receiving the battery supervisory control command, executes a sensing process at step S23. In the sensing process, the battery supervisory unit 44 acquires from the supervisory unit 44a via the selection circuit 47, and a conversion unit 44b converts the analog signal selected by the selection circuit 47 to be a digital signal and stores the converted signal into the memory unit 44c.

When the battery supervisory unit 44 senses the voltage of the battery cell 22, the battery supervisory unit 44 acquires a cell determination signal together with temperatures of respective battery cells 22 via the selection circuit 47 as the battery supervisory information and causes the memory unit 44c to store the acquired battery supervisory information. The voltage information of the battery cell 22 is sequentially stored with respect to time into the memory unit 44c of the battery supervisory unit 44. Further, in the command set, when one command includes a failure diagnosis control command, the voltage supervisory unit 44 performs a failure diagnosis of the own circuit.

Next, at step S24, the battery supervisory unit 44 transmits the acquired battery information to the wireless communication unit 46 via the microprocessor 45. At this moment, the battery supervisory unit 44 may transmit the cell determination signal together with the battery supervisory information including the temperature. Further, when performing the failure diagnosis process, the battery supervisory unit 44 responds with the failure diagnosis information. In the case where the microprocessor 45 is not provided, the voltage supervisory unit 44 directly transmits the information to the wireless communication unit 46. The wireless communication unit 46 of the supervisory unit 44 receives the information acquired by the battery supervisory unit 44. The wireless communication unit 46 spools (holds) the response data in the memory unit 46a and waits for the next process, the response data including the battery supervisory information to be transmitted to the control apparatus 50. The wireless communication unit 46 may hold the response data including the failure diagnosis data in the memory unit 46a and wait for the next process.

On the other hand, when the wireless communication unit 54 of the control apparatus 50 transmits the command set for n command executions at step S21 as described above, then a timer starts to counting time to determine a timing at which the response data is received. Thus, the wireless communication unit 54 is able to arbitrarily set the communication period in order to acquire, at a desired timing, the battery information acquired by the battery supervisory unit 44 of the supervisory apparatus 40. The communication period may be a fixed value for periodically executing a communication, or may be a variable value where the communication period is changed at each communication. That is, a timer setting value may be set to be a fixed value or a variable value. When the wireless communication unit 54 of the control apparatus 50 determines, based on the time measurement result by the timer, that it is a timing at which the response data can be received, the wireless communication unit 54 of the control apparatus 50 transmits a null command at step S25. The wireless communication unit 54 of the control apparatus 50 transmits the null command to the wireless communication unit 46 of the supervisory apparatus 40 at each communication period (refer to S25, S30, S35). The transmission period of the null command is determined corresponding to the fixed value or the variable value for one communication period as described above.

The battery supervisory unit 44 of the supervisory apparatus 40, when receiving a command with the battery supervisory control command at the transmission period of the command ser and the null command transmitted from the wireless communication unit 54 of the control apparatus 50, monitors the voltage information of a preassigned battery cells 22. The voltage supervisory unit 44 of the supervisory apparatus 40 monitors the voltage information of the assigned battery cells 22 at synchronize timing at which a predetermined time elapsed from a time when the above-described command set or the null command is received. Further, the battery supervisory units 44 of the plurality of supervisory apparatuses 40 each supervises the assigned battery cells of the battery assembly 12. At this time, the battery supervisory units 44 of the plurality of supervisory apparatuses 40 each acquires the voltage information of the assigned battery cell 22 for one or more times and causes the memory unit 44c to store the acquired information in a time-series manner. The battery supervisory units 44 of the supervisory apparatus 40 may execute a sensing process without synchronizing the transmission period of the command set and the null command. The wireless communication unit 46 of the supervisory apparatus 40, when receiving the null command, transmits the response data corresponding to the first command stored in the memory unit 46a at step S26.

As shown in FIG. 6, in the case where the wireless communication unit 46 of the supervisory apparatus 40 has received the voltage information of the battery cell 22 from the voltage supervisory unit 44 before receiving the null command from the wireless communication unit 54 of the control apparatus 50, the voltage information of the battery cell 22 stored in the memory unit 46a of the wireless communication unit 46 may be transmitted to the wireless communication unit 54 as the response data.

At this moment, the wireless communication unit 46 of the plurality of supervisory apparatuses 40 may sequentially read, from the memory unit 46a, the response data acquired in advance by the battery supervisory unit 44 and transmit the read response data in a FIFO (first in first out) manner, or the wireless communication unit 46 of the plurality of supervisory apparatuses 40 may read, from the memory unit 46a, the latest response data acquired from the battery supervisory unit 44 most recently and sequentially transmit the read response data in a LIFO (last in first out) manner. With the LIFO data, the latest voltage information of the battery cell 22 can be transmitted as the response data in a real time manner. Alternatively, the wireless communication unit 46 of the supervisory apparatus 40 may acquire only the latest voltage information of battery cell 22 for one communication frame as the response data and transmit the acquired voltage information to the wireless communication unit 54 of the control apparatus 50.

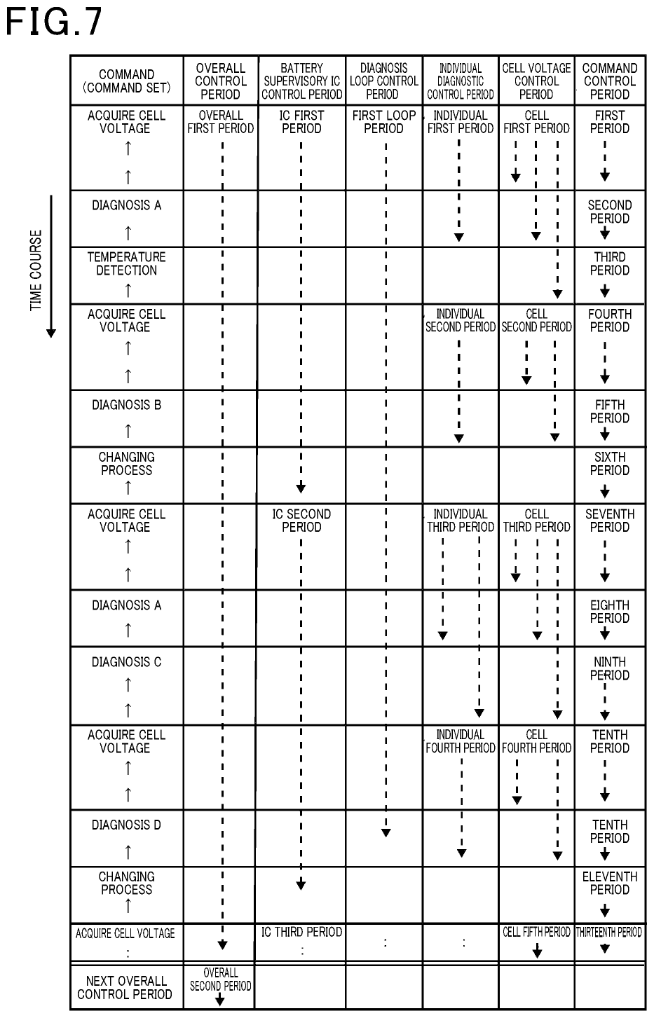

As will be later described in the second embodiment with reference to FIG. 7, in the case where the wireless communication unit 46 of the supervisory apparatus 40 receives the voltage information of the battery cell 22 from the battery supervisory unit 44 after receiving the null command from the wireless communication unit 54 of the control apparatus 50, the voltage information may be transmitted to the wireless communication unit 46 after the reception of the null command.

The wireless communication unit 46 of the supervisory apparatus 40 may transmit information related to the command received from the wireless communication unit 54 of the control apparatus 50 together with the battery information. Then, in the wireless communication unit 54 of the control apparatus 50 side, the reception thereof can be confirmed with the command associated with the battery information. Hence, the control apparatus 50 is able to reliably monitor the battery cell 22. The above-described ‘information related to command’ may be a command itself, or an output value produced accompanying with a process executed by the supervisory apparatus 40 based on the received command, or similar information thereof. The respective supervisory apparatuses 40 may transmit an identification ID showing own apparatus in addition to information related to the battery information or the command. At this time, the control apparatus 50 is able to reliably identify the battery information such that which one of the battery cells 22, and which one of a plurality of supervisory apparatuses 40, transmitted the battery information can be identified.

For example, when the supervisory unit 44a acquires the battery information, the battery supervisory unit 44 of the supervisory apparatus 40 causes a conversion unit 44b to convert the analog value of the battery information to be digital value and store the converted value into the memory unit 44b. The wireless communication unit 46, when receiving the battery information from the battery supervisory unit 44, integrates a command for causing the memory unit 44c to output the battery information externally and the battery information acquired based on the command for causing the memory unit 44c to output the battery information externally into the same communication frame, and transmits the communication frame to the wireless communication unit 54 of the control apparatus 50.

Then, the control apparatus 50 receives the command from the wireless communication unit 46 of the supervisory apparatus 40 and the battery information in the same communication frame, whereby the control apparatus is able to determine which supervisory apparatus 40 transmits the battery information from the wireless communication unit 46 thereof. In particular, the wireless communication unit 46 of the supervisory apparatus 40 utilizes two commands, a write command and an external output command, and the wireless communication unit 54 of the control apparatus 50 acquires the battery information based on the two commands. Hence, the control apparatus 50 is able to determine the reliability of the battery information. Thus, even in the case where either one command is corrupted due to a failure for example, the battery information as important information can be wirelessly transmitted with high reliability.

The wireless communication unit 54 of the control apparatus 50 receives the first response data at step S26. When the control apparatus 50 receives the battery information and the command from the wireless communication unit 46 of the supervisory apparatus 40, a sequence determination unit 54b determines whether the battery information and the command are correctly received in accordance with the sequence information indicating the sequence with which the battery information and the command is required to be received. In the case where the wireless communication unit 54 of the control apparatus 50 transmits a plurality of commands together to a plurality of supervisory apparatuses 40, it can be determined that the commands are sequentially transmitted as a combined unit to the wireless communication unit 46 of the supervisory apparatus 40. That is, the sequence information is utilized, whereby the commands can be correctly recognized as the combined unit.

For example, in the case where the sequence determination unit 54b determines that the battery information and the command are correctly received based on the sequence information indicating the sequence with which the battery information and the command is required to be received, the wireless communication unit 54 of the control apparatus 50 determines it OK, that is, the communication process is correctly performed, and the process proceeds to a process executed by the supervisory apparatus 50 after transmitting the first response data which will be described later.

Conversely, as a result of determination of the sequency determination unit 54b, when determined that the battery information and the command are not correctly received based on the sequence information, the wireless communication unit 54 of the control apparatus 50 may re-transmit a command set where a plurality of commands are combined to the wireless communication units 46 for all of the plurality of supervisory apparatuses 40. Alternatively, the wireless communication unit 54, when determined that the battery information and the command set are not correctly received based on the sequence information, the wireless communication unit 54 of the control apparatus 50 may re-transmit a command set where a plurality of commands are combined to the wireless communication units 46 only for the supervisory apparatuses 40 which are determined as incorrect (not correctly received). The wireless communication unit 54 of the control apparatus 50 may discard the response data transmitted as a response from the wireless communication units 46 of the supervisory apparatuses 50 which are determined as incorrect.

Next, a process executed by the supervisory apparatus 50 after transmitting the first response data will be described. The wireless communication unit 46 of the supervisory apparatus 40 transmits the first response data to the wireless communication unit 54 of the control apparatus 50. Thereafter, the wireless communication unit 46 transmits the second battery supervisory control command to the battery supervisory unit 44. The second battery supervisory control command indicates the second command included in the command set already transmitted at step S21.

The battery supervisory unit 44, when receiving the second battery supervisory control command, executes the sensing process at step S28 as described above. The battery supervisory unit 44 acquires, when executing the sensing process, temperature of each battery cell 22 together with the cell determination signal via the selection circuit 47. Further, in the case where the second command in the above-described command set includes a control command for failure diagnosis, the battery supervisory unit 44 performs a failure diagnosis of the own circuit.

Next at step S29, the battery supervisory unit 44 transmits the acquired voltage information of the battery to the wireless communication unit 46 via the microprocessor 45. At this moment, the battery supervisory unit 44 may transmit the battery supervisory information including the cell determination signal together with the temperature. Also, the battery supervisory unit 44 transmits the failure diagnosis information as a response when performing the failure diagnosis. In the case where the microprocessor 45 is not provided, the battery supervisory unit 44 directly transmits the information to the wireless communication unit 46.

Then, the wireless communication unit 46 of the supervisory apparatus 40, when receiving a periodically-transmitted null command corresponding to the second one at step S30, transmits the first response data stored in the memory unit 46a at step S31. The wireless communication unit 54 of the control apparatus 50 receives the second response data at step S31.

Thereafter, the wireless communication unit 46 of the supervisory apparatus 40 repeats the response similarly corresponding to the command included in the command set transmitted from the wireless communication unit 54 of the control apparatus 50.

For example, at steps S32 to S36 of the nth command and response, the wireless communication unit 46 of the supervisory apparatus 40 responds to the nth command included in the command set received from the wireless communication unit 54 of the control apparatus 50.

On the other hand, the wireless communication unit 54 of the control apparatus 50 determines, at a reception information determination unit 54a, whether all of the responses to the plurality of commands transmitted at the same time from the wireless communication unit 46 of the supervisory apparatus 40 and the battery information corresponds to the commands, are correctly received.

When the wireless communication unit 54 of the control apparatus 50 determines that the n-th response data is successively received at step S36, the wireless communication unit 54 of the control apparatus 50 transmits the response data to the main microprocessor 53. Such series of communication processes are performed between the control apparatus 50 and the plurality of supervisory apparatuses 40 using a unicast communication in a time-sharing manner. Hence, the control apparatus 50 is able to receive all response data from the plurality of supervisory apparatuses 40. Thus, the wireless communication unit 54 of the control apparatus 50 determines that all response data is received and the battery information corresponding to the command is received.

The control apparatus 50 is able to determine whether commands have reached all of the supervisory apparatuses 40 and the battery information corresponding to the commands have been successfully received. Note that, even when a part of the data is corrupted, data may be corrected using error correction technique to receive the correct data. In particular, the main microprocessor 53 of the control apparatus 50 may perform a control considering a reliable battery information data and adapting storage voltage data at which the battery cell indicates severe state. In this case, as long as the voltage state of the battery cell 22 of the battery assembly 12 is supervised under a constant state in a prescribed period, the battery cells 22 of the battery assembly 12 can be appropriately supervised.

The main microprocessor 53 of the control apparatus 50 reads the n-times response data received at steps S26, S31 and S36 from the plurality of supervisory apparatuses 40 and executes a predetermined process based on the response data at step S37.

At step S37, the main microprocessor 53 of the control apparatus 50 executes a predetermined process based on a plurality of battery supervisory information acquired in a predetermined period for example. Note that the control period refers to a period from a time when the command set is transmitted at step S21 to the predetermined process is completed to be executed at step S37, where any control process is completed in this period. In the example shown in FIG. 6, as a control period, a command control period is set. The detail of the command control period will be described later.

For example, the main microprocessor 53 of the control apparatus 50 according to the present embodiment acquires the voltage information of the battery cell 22 from the battery supervisory information acquired from the plurality of supervisory apparatus 40, and further acquires the current information with the current sensor 17 connected in series to the battery cell 22. The main microprocessor 53 of the control apparatus 50 predicts the internal resistance and an open circuit voltage of the battery cell 22 of the battery assembly 12 based on the voltage information and the current information.

The main microprocessor 53 of the control apparatus 50 is able to calculate the SOH (state of health) of the battery based on the predicted internal resistance. The SOH refers to an index showing a degree of deterioration. The main microprocessor 53 od the control apparatus 50 compares open-circuit voltages of the respective battery cells 22 and determines whether the open-circuit voltages are within a prescribed range. Hence, abnormality of the battery cell 22 can be detected. For the predetermined processes executed by the control apparatus, it is exemplified that the main microprocessor 53 mainly executes the predetermined processes. However, other configurations in the control apparatus 50, for example, the sub microprocessor 55 or the wireless communication unit 54 may execute them.

The main microprocessor 53 of the control apparatus 50 predicts the internal resistance and the open-circuit voltage of the battery cell 22 based on the voltage information and the current information of the battery cell 22. It is exemplified that the main microprocessor 53 of the control apparatus 50 calculates the SOH based on the predicted internal resistance and the open-circuit voltage. However, the prediction of the internal resistance and the open-circuit voltage, the calculation of the SOH are not limited to these examples.

For example, the microprocessor 45 of the supervisory apparatus 40 may perform a part of or all of operations among the prediction of the internal resistance and the open-circuit voltage and the calculation of the SOH. Also, the wireless communication unit 46 of the supervisory apparatus 40 may perform a part of or all of operations among the prediction of the internal resistance and the open-circuit voltage and the calculation of the SOH. The main microprocessor 53 of the control apparatus 50 may transmit, every time when the battery supervisory information is acquired, the acquired information to the host ECU 16, or may acquire the battery supervisory information, accumulate the acquired information and transmit the accumulated information to the host ECU at the same time.

After completing the communication processes corresponding to such a command set for one period, the wireless communication unit 54 of the control apparatus 50 transmits, at step S41, the next command set including commands of n command executions to the wireless communication unit 46 of the supervisory apparatus 40. The battery supervisory unit 44 of the supervisory acquires the battery supervisory information for responding to commands for n command executions included in the next command set, and the wireless communication unit 46 of the supervisory apparatus 40 transmits the response data to the wireless communication unit 54 of the control apparatus 50. Moreover, the wireless communication unit 54 of the control apparatus 50 communicates with the wireless communication units 46 of the plurality of supervisory apparatuses 40 using a unicast communication the time-sharing manner. Thus, processes are similarly repeated.

Next, a command set with a plurality of commands for one period and a control period will be described in detail. Firstly, a control period will be described in detail. In the above-description, the control period is defined as a period from a time when the command set is transmitted at step S21 to a time when the predetermined processes are completed at step S37, indicating a period where any control process is completed. In more detail, it can be exemplified as follows. FIG. 7 exemplifies a relationship between a plurality of commands that constitute a command set for one period and the control period. A required period or an amount of data for executing a process in the supervisory apparatus 40 side responding to the command transmitted by the wireless communication unit 54 of the control apparatus 50 differs between commands. In this respect, FIG. 7 shows an elapsed time corresponding to one command in the vertical direction.

The control period can be determined by a period depending on the battery supervisory control including a starting point of the battery control command to the end point thereof. As shown in FIG. 7, the control period can be categorized to overall control period, battery supervisory IC control period, diagnosis loop control period, individual diagnostic control period, cell voltage control period and command control period.

Next, a command control period will be described. FIG. 6 in the above description illustrates a case where the control period is a command control period as an example. In FIG. 7, the command control period is indicated as 1st period to 13rd period with a dashed line arrow, indicating periods corresponding to time required for executing commands such as a cell voltage acquisition command, a diagnosis A command to a diagnosis D command, a temperature detection command, a battery supervisory IC changing process command. In the left most column in FIG. 7 shows a type of commands (battery supervisory control command) included in the command set, and a dashed line arrow in FIG. 7 indicates a control period and a control duration of a command set where respective commands are combined.

The commands to be transmitted to the wireless communication unit 46 of the supervisory apparatus 40 from the wireless communication unit 54 of the control apparatus 50 can be categorized to the cell voltage acquisition command, the diagnosis A command to a diagnosis D command, the temperature detection command and the changing process command. The cell voltage acquisition command is transmitted to the supervisory apparatus 40 from the control apparatus 50 to command the supervisory apparatus 40 to acquire the voltage information of the battery cell 22.

The diagnosis A command to diagnosis D command are transmitted to the supervisory apparatus 40 from the control apparatus 50 to command the supervisory apparatus 40 to perform a failure diagnosis process. The diagnosis A, diagnosis B, diagnosis C and diagnosis D show mutually different types of failure diagnoses.

The temperature detection command is transmitted to the supervisory apparatus 40 from the control apparatus 50 to command the supervisory apparatus 40 to perform a temperature detection. The changing process command is used as a command to change the sequence of the battery supervisory IC. In the case where the wireless communication unit 54 of the control apparatus 50 sets a command control period as the control period, each command set is formed corresponding to any of the cell voltage acquisition commands, the diagnosis commands A, the diagnosis commands B, diagnosis commands C, the diagnosis command D, the temperature detection command and the changing process commands, and the same type commands are transmitted as one command set. In this example, a case is described in which a command set is set for one execution (n=1) commands. Note that, as indicated at the first period shown in FIG. 7, even it is n=1, commands are transmitted as a command set. In this example, a case of n=1 is exemplified. However, a plurality of commands may be combined as described below. The same applied to the following description for ‘n’.

For example, as sequentially indicated from the upper portion in FIG. 7, when the wireless communication unit 54 of the control apparatus 50 sets the cell voltage acquisition command to be a command set, the wireless communication unit 46 of the supervisory apparatus 40 transmits the voltage information of the battery cell 22 as a response data (see steps S24, S29, S34 in FIG. 6: 1st period in FIG. 7).

Thereafter, when the wireless communication unit 54 of the control apparatus 50 sets a diagnosis A command as a command set for a diagnosis process A, the wireless communication unit 46 of the supervisory apparatus 40 transmits a failure diagnosis result of the diagnosis A as the response data (See 2nd period shown in FIG. 7). Note that the 3rd to 13th periods are the same as the above-described operations, the explanation thereof will be omitted. As shown in FIG. 7, the command control period is shorter than the overall control period, the battery supervisory IC control period, the diagnosis loop control period, the individual diagnostic control period and the cell voltage control period.

Hereinafter, a cell voltage control period will be described.

As shown with a first cell period to fifth cell period indicated by a dashed line arrow in FIG. 7, the cell voltage control period includes at least a period from a time when starting to acquire information of the battery cell 22 to a time when completing the acquisition of the information of the battery cell 22. The cell voltage control period may include a period from when staring respective diagnosis to when completing the respective diagnosis or a period from when starting a temperature detecting to when completing the temperature detecting.

In the case where the wireless communication unit 54 of the control apparatus 50 sets a cell voltage control period as the control period, as indicated by a dashed line arrow in FIG. 7, cell voltage acquisition command (n=1), commands including cell voltage acquisition command and diagnosis A command (n=2), or commands including cell voltage acquisition command and diagnosis A command and temperature detection command (n=3) are each combined, that is, combined per n-number command such as command (n=1), commands (n=2) and commands (n=3), and the combined commands are transmitted as command sets (see first cell period in FIG. 7). Although other explanation will be omitted, as indicated by a right dashed line arrow corresponding to the third cell period shown in FIG. 7, a cell voltage acquisition command, a plurality of diagnosis command including a diagnose A command and a diagnose C command may be transmitted as a command set where these commands are combined.

For example, as indicated from the upper portion in FIG. 7, when the wireless communication unit 54 of the control apparatus 50 sets the commands including the cell voltage acquisition command to be a command set, the wireless communication unit 46 of the supervisory apparatus 40 transmits the voltage information of the battery cell 22 as a response (see left dashed line arrow corresponding to the first cell period shown in FIG. 7).

As indicated from the upper portion above in FIG. 7, when the wireless communication unit 54 of the control apparatus 50 sets the commands including the cell voltage acquisition command and the diagnosis A command to be a command set, the wireless communication unit 46 of the supervisory apparatus 40 sequentially transmits, as the first to n-th response data, the voltage information of the battery cell 22 and the failure diagnosis result of the diagnosis A in this order (see center dashed line arrow corresponding to the first cell period shown in FIG. 7).

As indicated from the upper portion in FIG. 7, when the wireless communication unit 54 of the control apparatus 50 sets the commands including the cell voltage acquisition command, the diagnosis A command and the temperature detection command to be a command set, the wireless communication unit 46 of the supervisory apparatus 40 sequentially transmits, as the first to n-th response data, the voltage information of the battery cell 22, the failure diagnosis result of the diagnosis A and the temperature detection result in this order (see right dashed line arrow corresponding to the first cell period shown in FIG. 7).

Since the second cell period to the fourth cell period shown in FIG. 7 are the same as the above-described operations, the explanation thereof will be omitted. As shown in FIG. 7, the cell voltage control period is shorter than the overall control period, the battery supervisory IC control period and the diagnosis loop control period.

Next, an individual diagnostic control period will be described.

The individual diagnostic control period indicates a period from when starting the acquisition of the voltage of the battery cell 22 to when the diagnosis process of the battery cell 22 is completed. The wireless communication 54 of the control apparatus 50, when setting an individual diagnostic control period to be the control period, commands including cell voltage acquisition command and diagnosis A command (n=2), or commands including cell voltage acquisition command and diagnosis B command (n=2) or commands including the cell voltage acquisition command and the diagnosis D command (n=2) are each combined, that is, combined per n-number command such as command (n=1), commands (n=2) and commands (n=3), and the combined commands are transmitted as a command set for n command executions.

For example, as indicated from the upper portion in the FIG. 7, the wireless communication 54 of the control apparatus 50, when setting the commands including the cell voltage acquisition command and the diagnosis A command to be a command set, the wireless communication unit 46 of the supervisory apparatus 40 sequentially transmits the voltage information of the battery cell 22 and the failure diagnosis result of the diagnosis A as the first to n-th response data in this order (see dashed line arrow corresponding to the individual first cell period shown in FIG. 7).

Since the individual second cell period to the individual fourth cell period shown in FIG. 7 are the same as the above-described operations, the explanation thereof will be omitted. As indicated by a right dashed line arrow corresponding to the individual third cell period shown in FIG. 7, a cell voltage acquisition command, a plurality of diagnosis command including a diagnose A command and a diagnose C command may be transmitted as a command set where these commands are combined (n=3). As a result, in the individual diagnosis period, the wireless communication unit 54 of the control apparatus 50 is able to receive any one of the failure diagnosis results of the diagnoses A to D. As shown in FIG. 7, the individual diagnosis control period is shorter than the overall control period, the battery supervisory IC control period and the diagnosis loop control period.

Hereinafter, a diagnosis loop control period will be described.

The diagnosis loop control period is a control period from when starting the acquisition of the voltage of the battery cell 22 to when the diagnosis process of the battery cell 22 is completed for executing all of the failure diagnoses of the diagnosis A to diagnosis D. When the wireless control unit 54 of the control apparatus 50 sets the diagnosis loop control period as the control period, a command set for n command executions is transmitted combining commands capable of performing a loop failure diagnosis including at least the cell voltage acquisition command and the diagnosis A command to diagnosis D command (see first loop period shown in FIG. 1). Further, a command set may be formed to include a temperature detection command and a changing process command which are included in the first loop period shown in FIG. 7. As a result, in the diagnosis first loop control period, the wireless communication unit 54 of the control apparatus 50 is able to receive all of the failure diagnosis results from the diagnosis A to diagnosis D. Next, the battery supervisory IC control period will be described. The battery supervisory IC control period includes a changing period of the battery supervisory IC that constitutes the supervisory unit 44a. The battery supervisory IC control period refers to a period for executing a reset or refresh process of a storage data of the memory unit 44c in the battery supervisory IC as a predetermined process at step S37 shown in FIG. 6. The battery supervisory IC period is provided, for example avoiding erroneous value being carried to the next control period.

The wireless communication unit 54 of the control apparatus 50 transmits a plurality of commands from first IC period to immediately before the second IC period as a command ser to the wireless communication units 46 of all of the supervisory apparatuses 40. The battery supervisory unit 44 executes processes responding to the plurality of commands included in the series of command sets, and sequentially transmits the response data depending on the plurality of commands to the wireless communication unit 54 of the control apparatus 50.

The battery supervisory unit 44 resets or refreshes the data stored in the registers in the memory unit 44c after receiving the changing process command. Thus, the processes can be continued to execute without leaving bug values or old voltage information in the memory unit 44c.

Hereinafter, the overall control period will be described.

The overall control period is longer than the control period of the battery supervisory IC of one supervisory apparatus 40, and indicates a period for controlling all control items of the battery supervisory IC of all of the battery supervisory units 44 included in the plurality of supervisory apparatuses 40. At this moment, the overall control period is defined as a period necessary for executing an output power control of the battery assembly 12 related to a travel control of the vehicle 10, an abnormality monitoring of all battery supervisory ICs in a prescribed period and an abnormality monitoring of the battery assembly 12 as a predetermined process.

The overall control period is longer than one communication period for receiving the response data from when the command set is transmitted. The wireless communication unit 54 of the control apparatus 50 transmits a command set including a plurality of commands from a first all period to immediately before a second all period as indicated by a dashed arrow shown in FIG. 7.

The wireless communication unit 54 of the control apparatus 50, when setting the overall control period as the control period, integrates the cell voltage acquisition command, the diagnosis A command to the diagnosis D command, the temperature detection command and the changing process command into one or a plurality of communication frames illustrated in the upper portion to the lower portion in FIG. 7, and transmits the communication frames as a command set for n command executions.

For example, as sequentially indicated from the upper portion in FIG. 7, when the cell voltage acquisition command is set in the command set, the wireless communication unit 46 of the supervisory apparatus 40 sequentially transmits the voltage information of the battery cell 22 as the response data thereof (see steps S24, S29 and S34 in FIG. 6). Thereafter, when the diagnosis command A is set in the command set, the wireless communication unit 46 of the supervisory apparatus 40 sequentially transmits the failure diagnosis result related to the diagnosis A as the response data thereof.

Further, the temperature detection command and the cell voltage acquisition command are set in the command set, the wireless communication unit 46 of the supervisory apparatus 40 sequentially transmits the temperature detection data and the voltage information of the battery cell 22. Although the explanation will be omitted for processes of subsequent commands, the wireless communication unit 54 of the control apparatus 50 executes the same communication process to the wireless communication units 46 of the plurality of supervisory apparatus 40 and receives these response data. Then, predetermined processes are executed, but the explanation thereof will be omitted.

Next, modification examples will be described.

According to the communication related to the series of command sets, an embodiment is exemplified in which the wireless communication unit 46 of the supervisory apparatus 40 transmits the first response data to the wireless communication unit 54 of the control apparatus 50 and then transmits the second battery supervisory control command to the battery supervisory unit 44. However, it is not limited to this sequence.

For example, the wireless communication unit 46 of the supervisory apparatus 40 may receive the null command at step S25, then may transmit, before transmitting the first response data at step S26, the second battery supervisory control command to the battery supervisory unit 44 at step S27.

Further, before or during execution of the predetermined process at step S37 by the main microprocessor 53 of the control apparatus 50, the wireless communication unit 54 of the control apparatus 50 may transmit the next command set including commands of n command executions to the wireless communication unit 46 of the supervisory apparatus 40. With this configuration, processes can be executed in parallel such that intervals can be shortened between n communication periods for communicating information related to the battery assembly 12 corresponding to one command set.

Further, the control apparatus 50 may confirm that all supervisory apparatuses 40 receive the command, and thereafter, the wireless communication unit 54 of the control apparatus 50 may transmit the next command set. Also, after the control apparatus 50 confirms that each supervisory apparatus receives the command, the wireless communication unit 54 of the control apparatus 50 may transmit the next command set sequentially to a supervisory apparatus 40 which has received the command among the supervisory apparatuses 40.

Hereinafter, technical meanings of the present disclosure will be described.

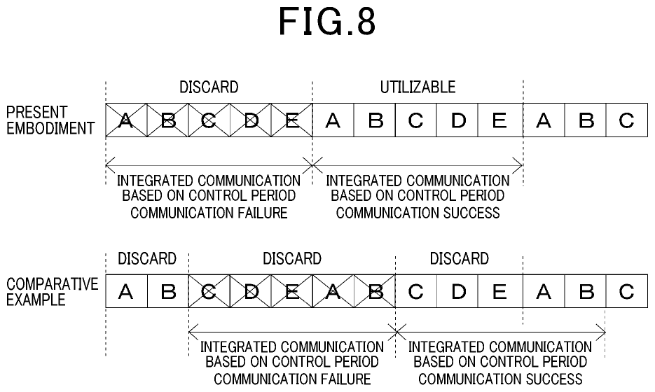

With reference to FIG. 8, technical meaning of the present disclosure will be described comparing the configuration of comparative examples. It is assumed that the wireless communication unit 54 of the control apparatus 50 transmits a command set where n commands (e.g. 5 commands: A, B, C, D, E commands shown in FIG. 8) are combined, and response data (e.g. RA+RB+RC+RD+RE) responding to these plurality of commands are processed with a predetermined process (e.g. battery control, travel control of the vehicle 10) at every control periods. FIG. 8 illustrates a combined communication from the control apparatus 50 side based on communication period. As illustrated in FIG. 8, in the case where C, D, E, A, B commands are combined and transmitted as a command set, when the communication of this command set fails, both response data in two adjacent control periods cannot be utilized.

In other words, in the case of an example illustrated in FIG. 8, the wireless communication unit 54 of the control apparatus 50 correctly receives only A, B response data in the previous control period and C, D, E response data in the following control period. As a result, meaningless data is received. Hence, response data in the previous and the following control periods should be discarded without completing both response data in the previous control period and the following control period.

According to the present embodiment, the wireless communication unit 54 of the control apparatus 50 is configured to wirelessly transmit the command set, where a plurality of commands are combined corresponding to the control period set for a control of monitoring the state of the battery assembly 12, to the wireless communication unit 46 of the supervisory apparatus 40.

The wireless communication unit 54 of the control apparatus 50 combines a plurality of commands based on the control period used for controlling the battery supervisory function and transmits the combined commands as a command set, thereby commanding a supervisory function of the battery state at every control period.

The wireless communication unit 54 of the control apparatus 50 is able to communicate to acquire the battery information acquired by the battery supervisory unit 44 of the supervisory apparatus 40 at a suitable timing and to acquire the data at each control period. As described in the above technical meaning, comparing to a case where commands are transmitted at an integrated communication period, communication errors can be suppressed.

In the above-described examples, since A+B+C+D+E commands are transmitted as a command set where a plurality of commands are combined, only one transmission to the supervisory apparatus 40 is required corresponding to the control period. Hence, a communication period can be set which is shorter than a time interval required for processing a task. As described in the above, comparing with a case where the commands are transmitted at every integrated communication period, an influence of communication error can be suppressed.

Also, the communication period for a communication of the information related to the battery assembly 12 for one time is set to be shorter than the control period for acquiring the voltages of all of the battery cells 22 and for a control. Specifically, the communication period for a communication of the information related to the battery assembly 12 for one time is set to be shorter than a period for acquiring the temperature information and the diagnosis information of all of the battery cells 22 to be monitored by the supervisory apparatus 40. Thus, a frequency of acquiring the battery information related to the battery assembly 12 can be higher.

The wireless communication unit 54 of the control apparatus 50 is configured to wait for a timing of transmitting the next command set where the next plurality of commands are combined until the response to the current command set including the plurality of commands currently transmitted at the same time is received from the wireless communication unit 46 of the supervisory apparatus 40. Then, the wireless communication unit 54 of the control apparatus 50 transmits, after receiving the response from the wireless communication unit 46 of all of the plurality of supervisory apparatuses 40, the next command set including the next plurality of commands to the supervisory apparatus 40.

For example, the battery supervisory units 44 of the plurality of supervisory apparatuses 40 are mutually synchronized and the battery supervisory units 44 each monitors corresponding battery cell 22. However, the battery supervisory unit 44 of specific supervisory apparatus 40 sometimes monitors the battery cell 22 relatively earlier or later than a battery supervisory unit 44 of other battery supervisory unit 44. Also, in this case, the wireless communication unit 54 of the control apparatus 50 waits for a timing of transmitting the next command set until all responses to the current command set are received. Accordingly, a monitoring timing of a specific supervisory apparatus 40 in the plurality of supervisory apparatuses 40 can be prevented from being changed from the monitoring timing of other supervisory apparatuses 40 as much as possible.

### Second Embodiment

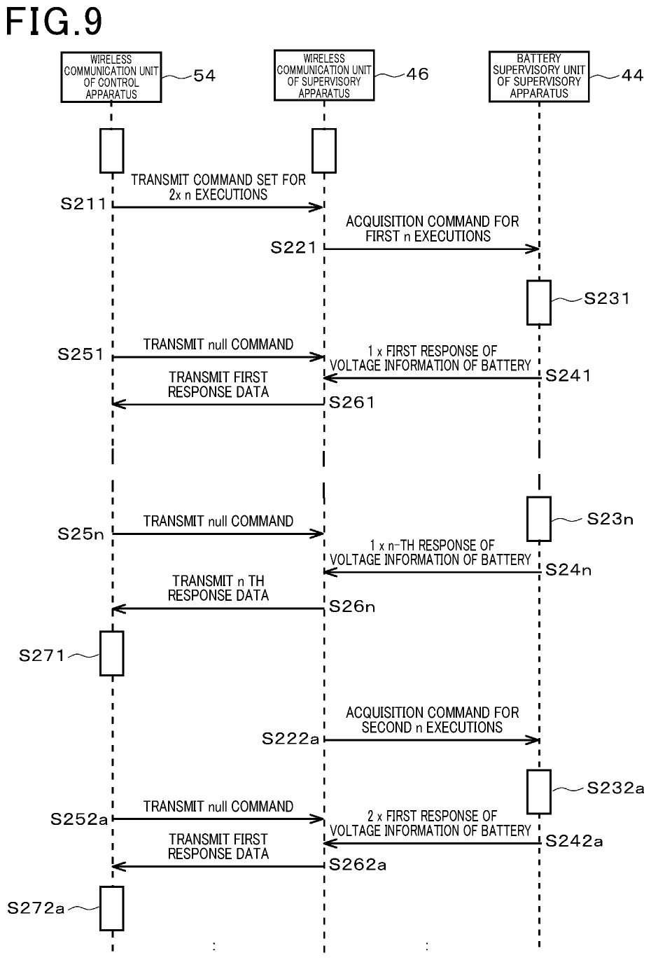

With reference to FIG. 9, a second embodiment will be described. According to the present embodiment, a case will be described in which the wireless communication unit 54 of the control apparatus 50 transmits a command set including 2×n commands (commands for 2×n executions) to the wireless communication unit 46 of the supervisory apparatus 40 in a periodical communication process. Hereinafter, configurations different from those in the first embodiment will mainly be described and explanation for the same configuration will be omitted.

In the periodical communication, as shown in FIG. 9, the wireless communication unit 54 of the control apparatus 50 transmits a command set including 2×n (n≥2) commands at step S211 to a supervisory apparatus 40 with which the connection process is completed, as one or more communication frames. At this moment, the wireless communication unit 54 of the control apparatus 50 transmits the command set to the wireless communication units 46 of a plurality of supervisory apparatuses 40 using a unicast communication in a time-sharing manner. That is, the command set where n commands are combined as described in the first embodiment is transmitted twice in the same time period.

The command set for one time execution combines n commands and is configured corresponding to a control period used for a control of monitoring the state of the battery assembly 12. The main microprocessor 53 of the control apparatus 50 receives a response data responding to one command set, thereby monitoring the state of the battery assembly 12.

Among commands for n command executions included in the one command set, a command of one execution includes a command for voltage monitoring of the battery assembly 12 and a control command for failure diagnosis, or a transmission request command of acquired information. The command for voltage monitoring of the battery assembly 12 indicates a command for acquisition request of the battery supervisory information. The control command for failure diagnosis indicates a command for acquisition request of the failure diagnosis information. Also, the transmission request command of the acquired information indicates a request command used for requiring transmitting the acquired information.

The wireless communication unit 46 of the supervisory apparatus 40, when receiving a command set including 2×n commands, issues a battery supervisory control command to the battery supervisory unit 44 at step S221. As shown in FIG. 7, the battery supervisory control command includes a battery monitoring command including acquisition command of the voltage information of the battery cell 22 for the first n executions and the transmission request command. Then, the acquisition request of the battery supervisory information is executed. The wireless communication unit 46 of the supervisory apparatus 40 according to the present embodiment transmits, with a battery supervisory control command, acquisition request of the voltage information of the battery cell 22 for the first n executions via the microprocessor 45. Here, the wireless communication unit 46 does not transmit the acquisition request of the voltage information for the second n-time executions to the battery supervisory unit 44.

The battery supervisory unit 44, when receiving the battery supervisory control command, executes a sensing process at step S231.

The battery supervisory unit 44 acquires, when executing the sensing process, a cell determination signal together with temperature of each battery cell 22 as the battery supervisory information via the selection circuit 47. Further, in the case where 1×1 command in the first command set including n commands includes a control command for a failure diagnosis, the battery supervisory unit 44 performs a failure diagnosis process for itself.

Next at step S241, the battery supervisory unit 44 transmits the acquired voltage information of the battery cell 22 to the wireless communication unit 46 via the microprocessor 45 as a voltage information of 1×1 battery cell 22 among 1×n acquisition commands. At this moment, the battery supervisory unit 44 may transmit the battery supervisory information including the temperature together with the cell determination signal. Further, the battery supervisory unit 44 transmits, when performing the failure diagnosis process, the failure diagnosis information as a response to the failure diagnosis.

In the case where the microprocessor 45 is not provided, the battery supervisory unit 44 directly transmits the information to the wireless communication unit 46. The wireless communication unit 46 of the supervisory apparatus 40 receives the information acquired by the battery supervisory unit 44. The wireless communication unit 46 generates a response data including the battery supervisory information to be transmitted to the control apparatus 50, stores the generated response data into the memory unit 46a and waits for next process. The wireless communication unit 46 may generate the response data including the failure diagnosis information and may stores in the memory unit 46a.

On the other hand, when the wireless communication unit 54 of the control apparatus 50 transmits a command set for 2×n executions as described above, the wireless communication unit 54 starts to measure, from this moment, a timing at which the response data is received using a timer. The wireless communication unit 54 may arbitrarily set the communication period such that the battery information acquired by the battery supervisory unit 44 of the supervisory apparatus 40 is obtained at suitable timing.

This communication period may be a fixed value or a variable value. That is, the timer setting value may be a fixed value or a variable value.

The wireless communication unit 54 of the control apparatus 50 transmits the null command at step S251 when the timer measurement value reaches a value indicating a timing for receiving the response data. The wireless communication unit 54 of the control apparatus 50 transmits the null command to the wireless communication unit 46 of the supervisory apparatus 40 (see steps S251 to S25n). The transmission period for the null command is determined corresponding to the fixed value or the variable value of one communication period as described above.

The wireless communication unit 46 of the supervisory apparatus 40, when receiving the null command, transmits 1×1 response data stored in the memory unit 46a to the wireless communication unit 54 of the control apparatus 50 at step S261.

The battery supervisory unit 44 of the supervisory apparatus 40 monitors the voltage information of the battery cell 22 of the battery assembly 12 asynchronously to the transmission period of the null command transmitted from the wireless communication unit 54 of the control apparatus 50. The transmission period of the null command corresponds to the communication period. Moreover, the battery supervisory units 44 of the plurality of supervisory apparatuses 40 also each monitor the voltage information of the corresponding battery cell 22 of the battery assembly 12.

As shown in FIG. 9, in the case where the wireless communication unit 54 of the control apparatus 50 receives the null command and then the wireless communication unit 46 of the supervisory apparatus 40 receives the voltage information of the battery cell 22 from the battery supervisory unit 44, after receiving the voltage information of the battery cell 22 at step S241, the wireless communication unit 46 of the supervisory apparatus 40 may transmit the received voltage information as the response data to the wireless communication unit 54.

Note that, as described in the first embodiment (see FIG. 6), in the case where the wireless communication unit 46 of the supervisory apparatus 40 receives the voltage information of the battery cell 22 from the battery supervisory unit 44, before receiving the null command from the wireless communication unit 54 of the control apparatus 50, the voltage information of the battery cell 22 stored in the memory unit 46a of the wireless communication unit 46 may be transmitted to the wireless communication unit 54 as the response data. The wireless communication unit 54 of the control apparatus 50 receives the 1×1 response data at step S261.

The battery supervisory unit 44 executes the sensing processes for n-executions at steps S231 to S23n in accordance with the first n acquisition commands included in the above-described battery control command. In this period, the battery supervisory unit receives the battery supervisory control command including the n acquisition commands at step S221. Hence, the battery supervisory unit 44 starts to count time by the timer whether it reaches a predetermined period from a time when the battery supervisory control command is received. The battery supervisory unit 44 periodically executes the sensing process at a time every time when the predetermined period elapses. Accordingly, even if the battery supervisory unit 44 does not receive the battery supervisory control command in the second execution timing or latter, the battery supervisory unit 44 is able to continue to execute the sensing process for n times while periodically measuring the time at S231 to S23n. The battery supervisory unit 44, when executing a sensing process, acquires a cell determination signal together with temperatures of respective battery cells 22 via the selection circuit 47 as the battery supervisory information. Further, in the case where the control command for the failure diagnosis is included in the above-described command set, the battery supervisory unit 44 performs a failure diagnosis process for itself.

The battery supervisory unit 44, when periodically executing the sensing process, transmits the voltage information of the battery cell 22 for n time executions at step A241 to S24n to the wireless communication unit 46 via the microprocessor 45 every time when the sensing process is executed. At this time, the battery supervisory unit 44 may transmit the cell determination signal together with the battery supervisory information including the temperature. Further, the battery supervisory unit 44 transmits, when performing the failure diagnosis, the failure diagnosis information as a response. When the microprocessor 45 is not provided, the battery supervisory unit 44 directly transmits the information to the wireless communication unit 46.

The wireless communication unit 46 of the supervisory apparatus 40, when receiving the null commands for n time executions from the wireless communication unit 54 of the control apparatus 50 at steps S251 to S25n, transmits the response data of the battery information to the wireless communication unit 54 at step S261 to S26n every time when the null command is received.

The wireless communication unit 54 of the control apparatus 50, when receiving the n-th response data at step S26n, transmits the response data to the main microprocessor 53 of the control apparatus 50. The series of such a communication process is performed between the control apparatus 50 and a plurality of supervisory apparatuses 40 using a unicast communication in a time-sharing manner. Hence, the control apparatus 50 is able to receive the response data from the plurality of supervisory apparatuses 40.

The main microprocessor 53 of the control apparatus 50 refers to the response data of n-time executions received from the plurality of supervisory apparatuses 40 at steps S261 to S26n, and executes the predetermined processes based on the response data at step S271. At step S271, the main microprocessor 53 of the control apparatus 50 executes the predetermined processes based on the plurality pieces of battery supervisory information acquired in the predetermines period.

For example, the main microprocessor 50 according to the present embodiment acquires the cell voltage values of the battery cells 22 based on the voltage information and the battery supervisory information acquired from the plurality of the supervisory apparatuses 40, and acquires cell current values from the current sensors 17 connected in series to the battery cells 22. The main microprocessor 53 of the control apparatus 50 estimates, based on these cell voltage values and the cell current values, the internal resistance and the open-circuit voltage of the battery cells 22 of the battery assembly 12. For the predetermined processes, since they are the same as those in the above-described embodiments, the explanation thereof will be omitted.

After completing such a communication process for the first command set, the wireless communication unit 46 of the supervisory apparatus 40 issues the next battery supervisory control command including the acquisition command for the second n-times executions at step 222a to the battery supervisory unit 44. At this moment, as described above, since the wireless communication unit 46 of the supervisory apparatus 40 has received the command set including 2×n commands at step S211, the second command set has also received at this time.

The wireless communication unit 46 transmits, at step S26n, the last n-th response data corresponding to the first command set, and then transmits, using an independently measured timing, the next battery supervisory control command at step S222a including the acquisition commands for the second n-executions to the battery supervisory unit 44.

Although the explanation is omitted since it is the same as those in the above-described configuration, the battery supervisory unit 44 of the supervisory apparatus 40 acquires the battery information responding to the acquisition command for the n-time executions included in the next battery supervisory control command, and the wireless communication unit 46 of the supervisory apparatus 40 transmits the response data to the wireless communication unit 54 of the control apparatus 50 (See FIG. 9, steps S252a, S242a, S262a . . . ). Then, the wireless communication unit 54 of the control apparatus 50 executes a predetermined process at step S272a.

Also, the wireless communication unit 54 of the control apparatus 50 is configured to communicate with the wireless communication units 46 of the plurality of supervisory apparatuses 40 using unicast communication in a time-sharing manner. Thus, the communication process is similarly repeated.

According to the present embodiment, the wireless communication unit 54 of the control apparatus 50 combines command sets including the first (current time) and second (next time) commands for 2×n-executions and transmits the combined command sets to the wireless communication units 46 of the supervisory apparatus 40. The wireless communication unit 46 of the supervisory apparatus 40 responds to the first (current) command set, and then the wireless communication unit 46 and the battery supervisory unit 44 of the supervisory apparatus 40 proceeds to the processes of the second (next) command set for one execution. Even with such an embodiment, similar effects and advantages can be obtained. According to the present embodiment, a case is described in which command sets including 2×n-executions commands are simultaneously transmitted, however, this is not limited thereto. For the command set, command sets of 3×n executions or more in the third time or later (next-next time or later) may be simultaneously transmitted. Also, in this case, similar effects and advantages can be obtained.

### Third Embodiment

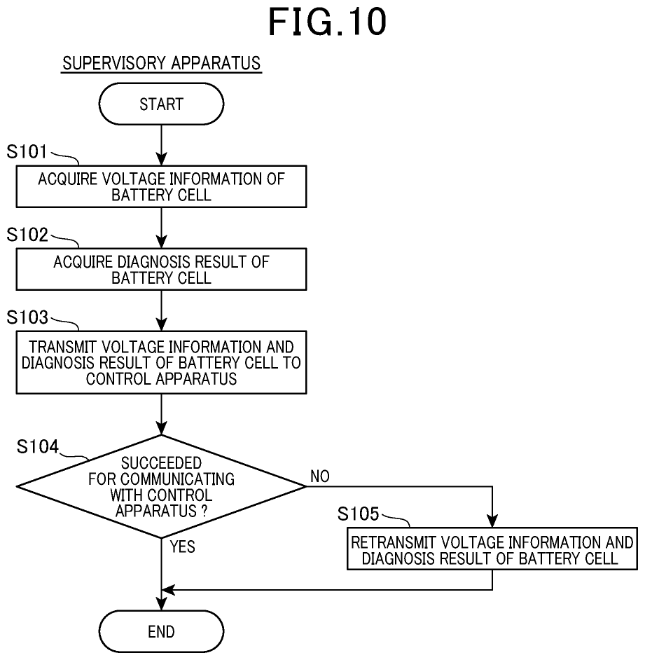

With reference to FIG. 10, a third embodiment will be described. With the third to fifth embodiments, processes executed in the case where the wireless communication between the control apparatus 50 and the supervisory apparatus 40 fails will be described.

Here, a case will be described in which the wireless communication unit 54 of the control apparatus 50 transmits, during a periodic communication process described in the first embodiment, a command set including a voltage acquisition command of the battery cell 22 and the failure diagnosis command, to the wireless communication unit 46 of the supervisory apparatus 40.

As shown in FIG. 10, the battery supervisory unit 44 of the supervisory apparatus 40 acquires, at step S101, the voltage information of the battery cell 22 as the battery supervisory information and the battery information, performs a failure diagnosis of the battery cell 22 based on the battery information at step S102 to acquire the failure diagnosis information. Thereafter, the wireless communication unit 46 of the supervisory apparatus 40 transmits, at step S103, the battery information including the voltage supervisory information and the failure diagnosis information as the response data to the wireless communication unit 54 of the control apparatus 50.

The wireless communication unit 46 of the supervisory apparatus 40 confirms a reception acknowledge of the wireless communication unit 54. The wireless communication unit 46 is able to determine that the communication is successful at step S204 when confirming a reception acknowledge. However, the wireless communication unit 46, when the reception acknowledge is not correctly received, retransmits the response data of the battery information transmitted in advance at step S105. That is, the wireless communication unit 46 of the supervisory apparatus 40 retransmits the battery information such as the voltage information of the battery cell 22 together with the failure diagnosis information of the battery cell 22 to the wireless communication unit 54 of the control apparatus 50. Thus, the wireless communication unit 46 of the supervisory apparatus 40 is able to reliably transmit the battery information related to the battery cell 22 which is monitored by this supervisory apparatus 40 to the wireless communication unit 54.

Summary of the above-described embodiment will be described.

The supervisory apparatus 40 performs a diagnosis of the battery cell 22 based on the battery information including the information indicating the state of the battery cell 22, and transmits the battery information and the diagnosis result of the battery cell 22. Then, the wireless communication unit 46 of the supervisory apparatus 40 retransmits the battery information and the diagnosis result of the battery when failing the wireless communication between the control apparatus 50 and the wireless communication unit 54.

According to the present embodiment, not only the failure diagnosis information of the battery cell 22 but also the battery information can be retransmitted, thereby detecting an abnormality of not only a diagnosis of a failure on the voltage information of the battery but also a failure occluding in the internal circuit of the supervisory apparatus 40. As a result, the main microprocessor 53 of the control apparatus 50 is able to check the cause of failure diagnosis result of the battery cell 22 in detail together with the battery information of the battery cell 22 in the battery assembly 12.

### Fourth Embodiment

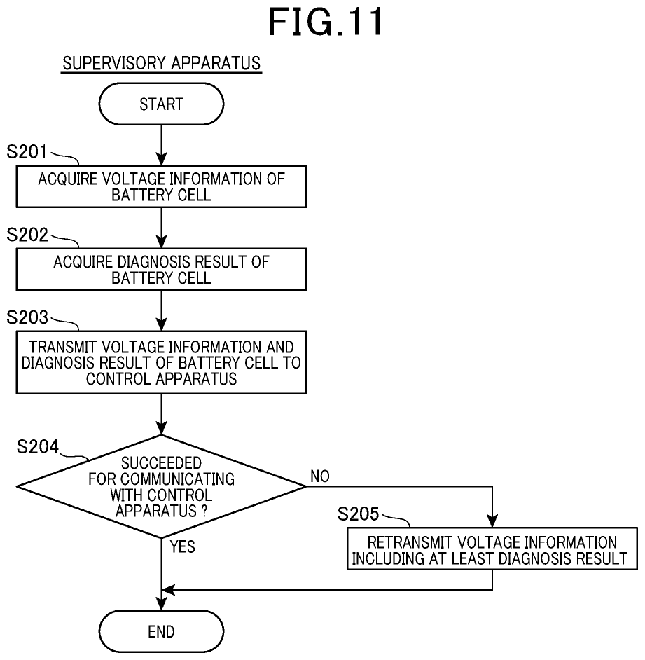

With reference to FIG. 11, a fourth embodiment will be described. Here, a case will be described in which the wireless communication unit 54 of the control apparatus 50 transmits, in the periodic communication process described in the first embodiment, a command set including the voltage acquisition command of the battery cell 22 and the failure diagnosis command to the wireless communication unit 46 of the supervisory apparatus 40.

As shown in FIG. 11, the battery supervisory unit 44 of the supervisory apparatus 40 acquires, at step S201, the voltage information of the battery cell 22 as the battery supervisory information and the battery information, and performs a failure diagnosis of the battery cell 22 based on the battery information to acquire the failure diagnosis information at step S202. Thereafter, the wireless communication unit 46 of the supervisory apparatus 40 transmits, at step S203, the battery information including the voltage supervisory information and the failure diagnosis information as the response data to the wireless communication unit 54 of the control apparatus 50.

The wireless communication unit 46 of the supervisory apparatus 40 confirms a reception acknowledge from the wireless communication unit 54. The wireless communication unit 46 determines that the communication is successful when the reception acknowledge is confirmed at step S204. However, when the wireless communication unit 46 does not receive the reception acknowledge correctly, the wireless communication unit 46 retransmits, at step S205, at least the response data with the battery information including the diagnosis result of the battery cell 22.

Specifically, the wireless communication unit 46 of the supervisory apparatus 40 retransmits at least the failure diagnosis information of the battery cell 22 to the wireless communication unit 54 of the control apparatus 50. At this moment, the wireless communication unit 46 of the supervisory apparatus 40 does not retransmit a part of or whole battery information, but retransmits the diagnosis result of the battery cell 22 as important data. Thus, the wireless communication unit 46 of the supervisory apparatus 40 is able to reliably transmit the diagnosis information of the battery cell 22 which is monitored by this supervisory apparatus 40 to the wireless communication unit 54.

Summary of the above-described embodiment will be described.

The supervisory apparatus 40 performs a diagnosis of the battery cell 22 based on the battery information and transmits the battery information and the diagnosis result of the battery to the control apparatus 50. Then, the wireless communication unit 46 of the supervisory apparatus 40 retransmits, when failing the wireless communication between the control apparatus 50 and the wireless communication unit 54, at least the battery information including the diagnosis result of the battery cell 22.

At this moment, the wireless communication unit 46 of the supervisory apparatus 40 does not retransmit a part of or whole battery information, but retransmits the diagnosis result of the battery cell 22. Hence, an amount of data can be reduced compared to a case of retransmitting whole data when failing the communication. Hence, the reliability and the certainty of communication when retransmitting the data can be improved.

### Fifth Embodiment

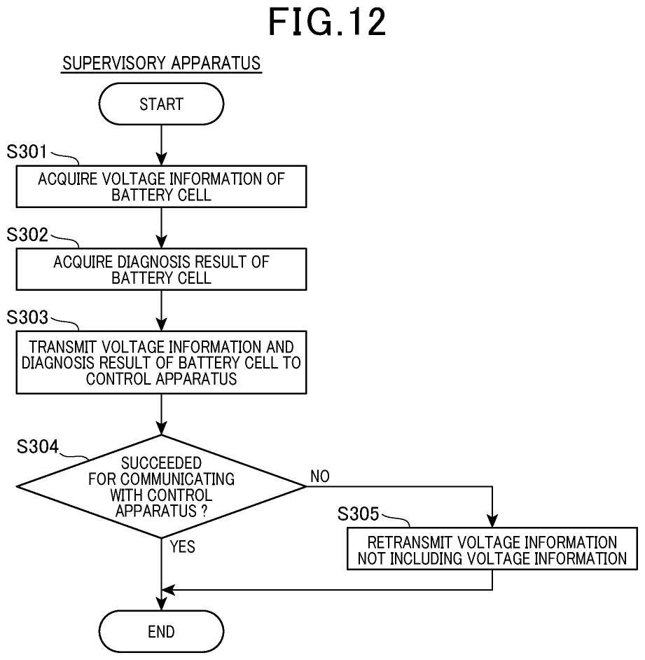

With reference to FIG. 12, a fifth embodiment will be described. Here, a case will be described in which the wireless communication unit 54 of the control apparatus 50 transmits, in the periodic communication process described in the first embodiment, a command set including the voltage acquisition command of the battery cell 22 and the failure diagnosis command to the wireless communication unit 46 of the supervisory apparatus 40.

As shown in FIG. 12, the battery supervisory unit 44 of the supervisory apparatus 40 acquires, at step S301, the voltage information of the battery cell 22 as the battery supervisory information and the battery information, and performs a failure diagnosis of the battery cell 22 based on the battery information to acquire the failure diagnosis information at step S302. Thereafter, the wireless communication unit 46 of the supervisory apparatus 40 transmits, at step S303, the battery information including the voltage supervisory information and the failure diagnosis information as the response data to the wireless communication unit 54 of the control apparatus 50.

The wireless communication unit 46 of the supervisory apparatus 40 confirms a reception acknowledge from the wireless communication unit 54. The wireless communication unit 46 determines that the communication is successful when the reception acknowledge is confirmed at step S304. However, when the wireless communication unit 46 does not receive the reception acknowledge correctly, the wireless communication unit 46 retransmits, at step S305, at least the response data with the battery information not including the voltage information of the battery cell 22.

The wireless communication unit 46 of the supervisory apparatus 40 retransmits the failure diagnosis information of the battery cell 22 to the wireless communication unit 54 of the control apparatus 50. At this moment, the wireless communication unit 46 of the supervisory apparatus 40 does not retransmit the voltage information data of the battery cell 22 but retransmits the diagnosis result of the battery cell 22. The voltage information of the battery cell 22 has a relatively large amount of data and an acquisition frequency is higher than other battery information. Since the wireless communication unit 46 of the supervisory apparatus 40 does not retransmit the voltage information of the battery cell 22 having a large amount of data and a high acquisition frequency, an amount of data to be transmitted can be reduced. Thus, other important data such as the diagnosis result of the battery assembly 12 can be transmitted prior to the voltage information of the battery cell 22. According to the present embodiment, the wireless communication unit 46 of the supervisory apparatus 40, since the wireless communication unit 46 of the supervisory apparatus 40 does not retransmit the voltage information of the battery cell 22, data having high importance can be the response data while reducing an amount of transmission data.

### Sixth Embodiment

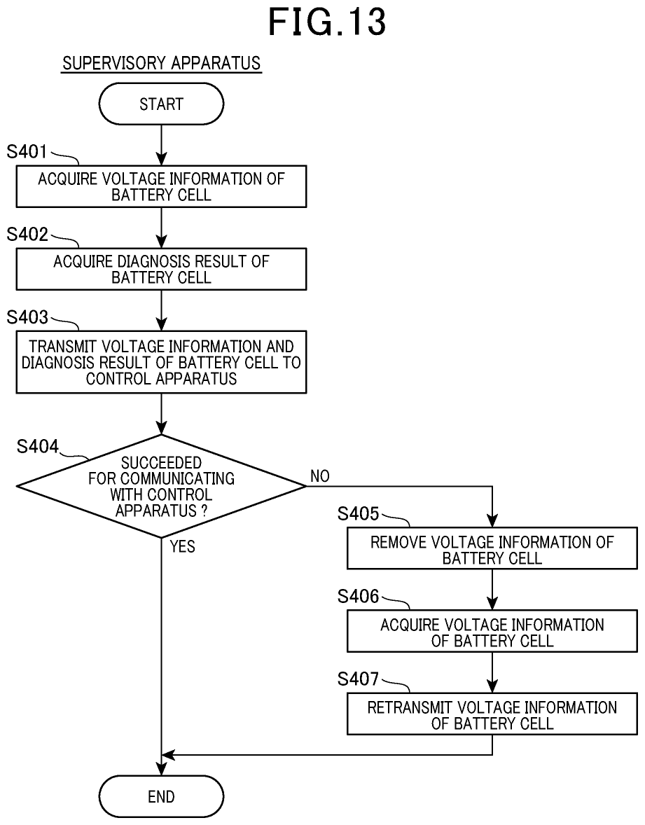

With reference to FIG. 13, a sixth embodiment will be described. The main microprocessor 53 of the control apparatus 50 may preferably acquire the latest voltage information of the battery cell 22 to calculate various information. Hence, the battery supervisory unit 44 of the supervisory apparatus 40 may frequently acquire the voltage of the battery cell 22 at a shorter period. Further, since the battery supervisory unit 44 acquires the voltage information of plenty of battery cells 22 in a time-series manner, an amount of these data is likely to be larger. Accordingly, the battery supervisory unit 44 of the supervisory apparatus 40 may gradually remove older data from the memory unit 44c.

In this respect, the supervisory apparatus 40 may execute processes as shown in FIG. 13. Here, a case will be described in which the wireless communication unit 54 of the control apparatus 50 transmits, in the periodic communication process described in the first embodiment, a command set including the voltage acquisition command of the battery cell 22 and the failure diagnosis command to the wireless communication unit 46 of the supervisory apparatus 40.

As shown in FIG. 13, the battery supervisory unit 44 of the supervisory apparatus 40 acquires, at step S401, the voltage information of the battery cell 22 as the battery supervisory information and the battery information, and performs a failure diagnosis of the battery cell 22 based on the battery information to acquire the failure diagnosis information at step S402. Thereafter, the wireless communication unit 46 of the supervisory apparatus 40 transmits, at step S403, the battery information including the voltage supervisory information and the failure diagnosis information as the response data to the wireless communication unit 54 of the control apparatus 50.

The wireless communication unit 46 of the supervisory apparatus 40 confirms a reception acknowledge from the wireless communication unit 54. The wireless communication unit 46 determines that the communication is successful when the reception acknowledge is confirmed at step S404. However, when the wireless communication unit 46 does not receive the reception acknowledge correctly, the battery supervisory unit 44 removes the voltage information of the battery cell 22 stored in the memory unit 44c at step S405. At this moment, the battery supervisory unit 44 may remove the voltage information from the oldest acquired data among the acquired voltage information of the battery cell 22. Similarly, the wireless communication unit 46 may gradually remove data from the memory unit 46a.

Thereafter, the battery supervisory unit 44 of the supervisory apparatus 40 again acquires the voltage information of the battery cell 22 at step S406, and retransmits the voltage information of the battery cell 22 at step S407. Thus, the battery supervisory unit 44 of the supervisory apparatus 40 newly acquires the voltage information of the battery cell 22 and retransmits the acquired voltage information while removing older data.

The battery supervisory unit 44 of the supervisory apparatus 40 diagnoses the battery cell 22 based on the voltage information of the battery cell 22 at step S402 to acquire the diagnosis result.

Since the diagnosis information is important data which will be utilized in the later analysis, the diagnosis information may preferably be continuously stored in the memory unit 46a or 44c without removing it from the memory unit 46a or 44c. At this moment, the diagnosis information may be stored in the memory unit 44c of the battery supervisory unit 44 or may be stored in the memory unit 46a of the wireless communication unit 46. Thus, the battery cell 22 can be effectively monitored and the memory capacity of the memory units 44c and 46a can be prevented from being lowered.

### Seventh Embodiment

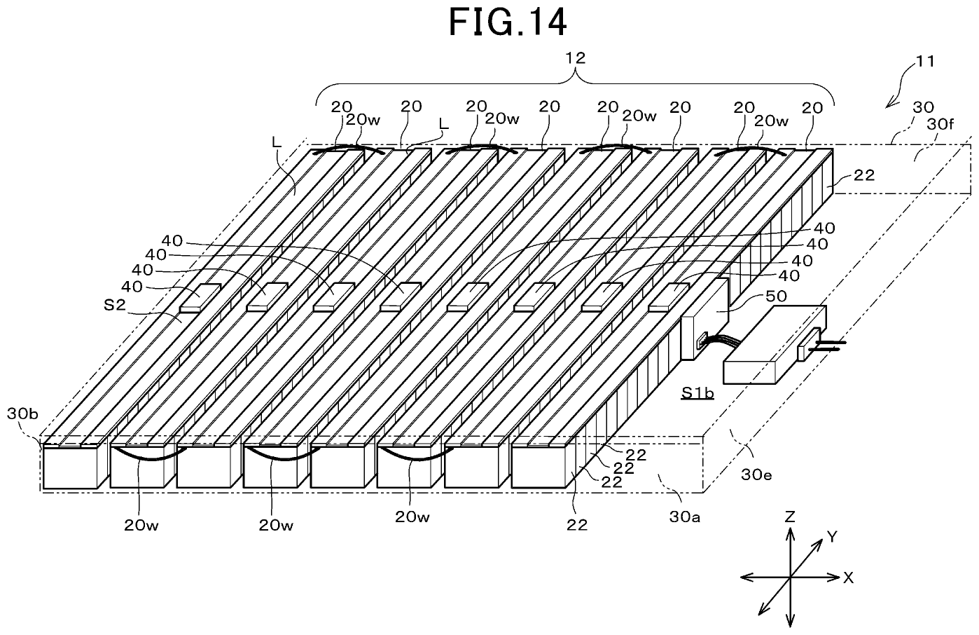

With reference to FIG. 14, a seventh embodiment will be described. As shown in FIG. 14, supervisory apparatuses 40 may be disposed on respective upper surfaces of a plurality of battery modules 20. The supervisory apparatus 40 is disposed at a center position of the battery module 20 extended in the Y direction, connecting a detection line L in the both directions of the Y direction. FIG. 14 exemplifies a case where the supervisory apparatus 40 is disposed at a center position in the Y direction on the upper surface of each battery module 20. However, the supervisory apparatus 40 is not necessarily disposed at the center position in the Y direction. That is, it is not limited to the center position and the supervisory apparatus 40 may be disposed at any positions as long as it is in an intermediate position in the Y direction.

The supervisory apparatuses 40 are each provided with a battery supervisory unit 44 mounted thereon, having a detection line L connected thereto. The battery supervisory unit 44 is configured of an integrated circuit unit composed of one or more battery supervisory ICs. The battery supervisory unit 44 can detect the voltages of the plurality of battery cells in the respective battery modules 20 using the detection line L. The upper end of the supervisory apparatus 40 is provided protruding in the Z direction relative to the bus bar cover 27.

Similar to the above-described embodiments, the control apparatus 50 is provided with the wireless communication unit 54 mounted thereon, and the supervisory apparatus 40 is provided with the wireless communication unit 46 mounted thereon. The housing 30 includes a gap in an upper inner end with respect to the Z direction. The gap serves as a propagation space S2 for the wireless communication. The control apparatus 50 is able to perform a wireless communication with a plurality of supervisory apparatuses 40 via the propagation space S2. As long as the wireless communication unit 54 of the control apparatus 50 communicates with the wireless communication units 46 of the plurality of supervisory apparatuses 40 with direct waves, an environment of the wireless propagation can be favorably maintained.

Since the supervisory apparatus 40 is disposed protruding from the upper end of the bus bar cover 27, electromagnetic waves propagate through the propagation space S2 which is positioned on an upper side relative to the upper end of the bus bar cover 27, whereby the control apparatus 40 readily communicates with the supervisory apparatus 40. According to the present embodiment, the supervisory apparatus 40 may not be disposed on the side surface in the Y direction (Y-side surface). Hence, a width in the Y direction of the housing 30 can be reduced such that small-sized housing 30 can be accomplished.

### Eighth Embodiment

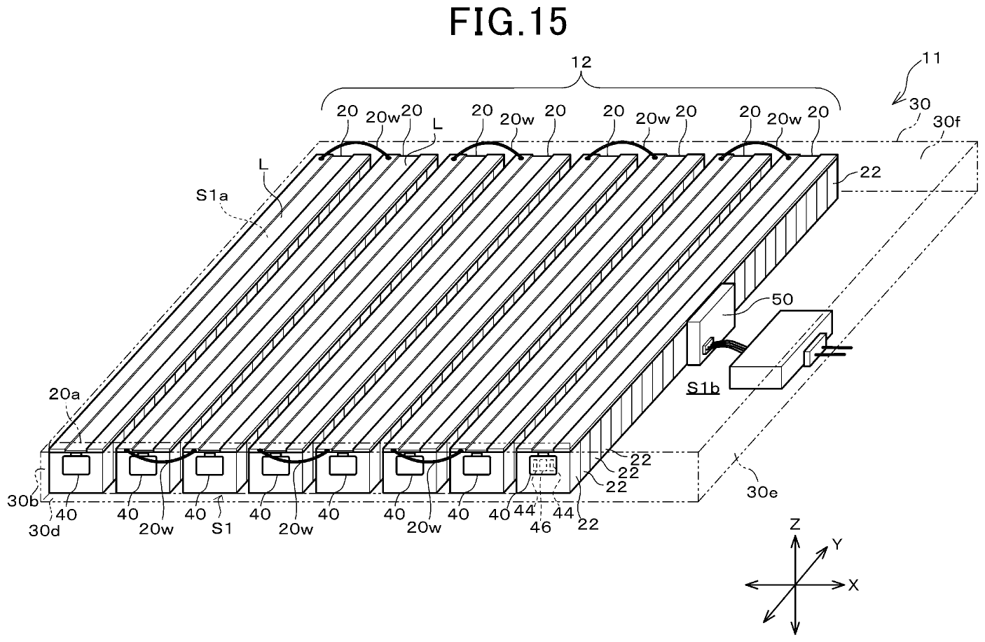

With reference to FIG. 15, an eighth embodiment will be described. As shown in FIG. 15, the supervisory apparatuses 40 are arranged on the Y-side surfaces of the respective battery modules 20. The supervisory apparatus 40 is provided with a wireless communication unit 46 and the battery supervisory unit 44. The battery supervisory unit 44 is connected to the detection line L. A plurality of battery supervisory units 44 may be provided in each of the supervisory apparatus 40. The battery supervisory unit 44 is connected to one end of the detection line L extended in the Y direction, whereby the voltage of the battery cell 22 can be detected.

Similar to the first embodiment, a space S1 is provided in an inner side of a first wall surface 30a of the housing 30. For the wireless communication unit 54 of the control apparatus 50, the space S1 is used as a pseudo waveguide space between the wireless communication unit 54 and the wireless communication units 46 of the plurality of supervisory apparatuses 40, thereby performing the wireless communication. A plurality of supervisory apparatuses 40 are arranged repeatedly along the X direction at constant intervals, for example. Even with such an arrangement of the eighth embodiment, similar to the first embodiment, low height arrangement can be accomplishment.

### Ninth Embodiment

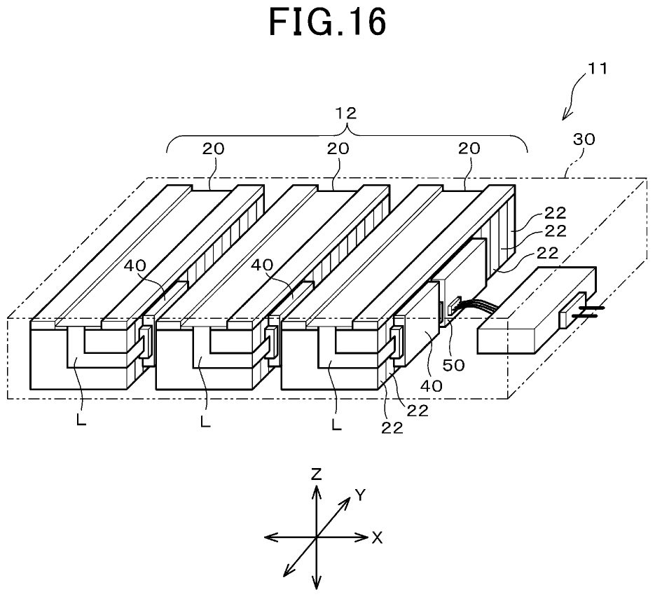

With reference to FIG. 16, a ninth embodiment will be described. As shown in FIG. 16, the supervisory apparatuses 40 are arranged on side surfaces in the X direction (X-side surfaces) of the respective battery modules 20. The detection line L is provided along the upper surfaces of the respective battery modules 20, extending to the X-side surface via the Y-side surface on which the detection line L is bent in a L shape, and further extending along the Y direction to be connected to the supervisory apparatus 40 on the X-side surface.

Similar to the above-described embodiments, the control apparatus 50 is connected to the plurality of supervisory apparatuses 40 by wireless connection. Even with such an arrangement of the ninth embodiment, similar to the first embodiment, low height arrangement can be accomplishment. According to the present embodiment, the supervisory apparatus 40 may not be disposed on the Y-side surface. Hence, a width in the Y direction of the housing 30 can be reduced such that small-sized housing 30 can be accomplished.

Moreover, since the supervisory apparatus 40 is not necessarily disposed on the upper surface of the battery module 20, the height of the housing 30 in the Z direction can be reduced so that the size of the housing 30 can be smaller. In the case where a connection environment for the communication between the control apparatus 50 and the plurality of supervisory apparatuses 40 is critical, the space S1 or the space S2 which are described in the above embodiments may be provided in an end portion in the Y direction of the housing or an upper end portion in the Z direction of the housing 30.

### Other Embodiments

It is not limited to the above-described embodiments. For example, the configurations of the present disclosure may be modified or expanded as follows. In the above-described embodiments, a case is described in which the battery supervisory system 1 is mounted on the vehicle 10. However, it is not limited to a system mounted on the vehicle 10. For example, the present disclosure may be applied to a battery supervisory system 1 which is stationarily placed at an indoor place or an outdoor place. For example, a battery supervisory system 1 may be configured such that the control apparatus 50 and the supervisory apparatuses 40 are installed in a battery exchange station or a battery rack, wirelessly communicating with each other.

According to the above-described embodiment, a case is exemplified in which the communication period is set to be shorter than the control period. However, it is not limited to this embodiment. The communication period may be the same as the control period or may be longer than the control period. Moreover, when the communication period for communicating the information related to the battery assembly 12 for one time is set to be shorter than the control period for acquiring voltages of all battery cells 22 and a period for respective supervisory apparatuses 40 to acquire the temperature information and the failure diagnosis results of all battery cells 22, a frequency of acquiring the battery information related to the battery assembly 12 can be higher.

The above-described embodiments exemplify a battery supervisory system 1 in which a plurality of supervisory apparatuses 40 are provided as a star-connected network of which the center is the control apparatus 50 to be capable of performing a packet communication. However, the network topology between the control apparatus 50 and the supervisory apparatuses 40 is not limited to this example.

The control apparatus 50 and the supervisory apparatuses 40 may be connected to form a mesh network. Alternatively, the control apparatus 50 and the supervisory apparatuses 40 may be a network configured of at least two mixed networks among a star-connected network, a mesh network and a daisy-chain network. The network configuration here is that a plurality of supervisory apparatuses 40 are grouped and connected with wired lines to constitute one network, and the grouped supervisory apparatuses 40 function as a one device. This mesh network is configured by a topology in which the control apparatus 50 and a plurality of supervisory units form a network.

A daisy-chain network connection may be applied to the control apparatus 50 and the supervisory apparatuses 40. Alternatively, the control apparatus 50 and the supervisory apparatuses 40 may be a network configured of at least two mixed networks among a star-connected network, a mesh network and a daisy-chain network. For the control apparatus 50 and the supervisory apparatus 40, a configuration of a wireless connection network is exemplified. However, a wired connection network may be utilized mixing to the wireless connection network. Thus, the network topology for the control apparatus 50 and the supervisory apparatus 40 is not limited to any specific topology.

For example, the wireless communication unit 46 may be divided into a wireless transmission unit and a wireless reception unit. The supervisory apparatus 40 may be configured without the microprocessor 45. That is, the wireless communication unit 46 may be configured of only the wireless IC to communicate with the battery supervisory unit 44. Further, a sensing control by the battery supervisory unit 44 and a schedule control for self-diagnosis may be executed by the main microprocessor 53 of the control apparatus 50.

According to the above-described embodiments, a case is exemplified in which the main microprocessor 53 of the control apparatus 50 estimates an internal resistance and an open-circuit voltage of the battery cell 22 based on the cell voltage and the cell current, and calculates the SOH based on the estimated internal resistance and the open-circuit voltage. However, the estimation of the internal resistance and the open-circuit voltage, and the calculation of the SOH are not limited to the above example. For example, in the estimation of the internal resistance and the open-circuit voltage, and the calculation of the SOG, a part of or all of processes may be performed by an internal unit of the supervisory apparatus 40, for example, the wireless communication unit 46.

The above-described embodiments exemplify a case where the supervisory apparatus 40 acquires the battery related information. However, it is not limited thereto. The supervisory apparatus 40 may autonomously acquire the battery related information and may transmit the stored battery related information to the control apparatus 50 in accordance with a transmission request of the control apparatus 50.

According to the above-described embodiments, it is exemplified that a plurality of supervisory apparatuses 40 are star-connected with the center control apparatus 50 as the center apparatus. However, the network topology between the control apparatus 50 and the supervisory apparatuses 40 is not limited to this example. For the network topology, a wired connection network may be mixed to the wireless network. Thus, the network topology between the control apparatus 50 and the supervisory apparatuses 40 is not limited to a specific configuration.

The arrangement of the battery modules 20 and the battery cells 22 constituting the battery assembly 12 and the number of battery modules 22 and the battery cells 22 are not limited to the above-described embodiments. The arrangement of the supervisory apparatus 40 and/or the control apparatus 50 in the battery pack 11 is not limited to the above-described embodiments.

In the above-described embodiments, a case is exemplified in which one control apparatus 50 is provided in the battery pack 11. However, it is not limited thereto. A plurality of control apparatuses 50 may be provided in the battery pack 11.

In other words, a plurality of supervisory apparatuses 40 and one or more control apparatuses 50 may be provided in the battery pack 11. A wireless communication system built between the control apparatus 50 and the plurality of supervisory apparatuses 40 may be provided in the battery pack 11 as a plurality of wireless communication systems.

According to the above-described embodiment, a case is exemplified in which the supervisory apparatus 40 is provided with one supervisory unit 44. However, it is not limited to this configuration. A plurality of battery supervisory units 44 (sensor ICs) may be provided. Further, the wireless communication unit 46 may be configured not to include a microprocessor 45. In this case, the main microprocessor 53 may constitute a part of the function of the wireless communication unit 46.

In the above-described embodiments, one supervisory apparatus 40 is provided at every one or two battery modules 20 as an example. However, this is not limited thereto. For example, one supervisory apparatus 40 may be provided at every three or more battery modules 20. For example, two or more supervisory apparatuses 40 may be provided at one battery module 20.

In the above-described embodiments, a case is exemplified in which one battery module 20 is formed as one group and a plurality of groups are arranged in parallel to be accommodated in the battery pack 11. However, it is not limited to this configuration. The one group is not necessarily one battery module 20, a one battery stack and one battery block as a unit of group. The battery cells 22 divided from one battery module may be regarded as one group. Moreover, for example, with a cell to pack or a cell to chassis configuration, the battery cells 22 may be accommodated as pack in the vehicle 10 in a module-less manner. In this case, one or more battery cells 22 may be regarded as a group.

The supervisory apparatus 40 may be disposed across a plurality of groups of the battery cells 22. In this case, a plurality of battery units 44 may be each provided at each group. The supervisory apparatus 40 may be provided at each group. In this case, the battery supervisory unit 44 may be configured to monitor the battery cells 22 for each group. The number of battery cells 22 included in respective groups may not the same or different between groups.

The control apparatus 50, a supervisory apparatus 40, a host ECU 16 and method thereof disclosed in the present disclosure may be accomplished by a dedicated computer constituted of a processor and a memory programmed to execute one or more functions embodied by computer programs. Alternatively, the control apparatus 50, the supervisory apparatus 40, the host ECU 16 and method thereof disclosed in the present disclosure may be accomplished by a dedicated computer provided by a processor configured of one or more dedicated hardware logic circuits.

Further, the control apparatus 50, the supervisory apparatus 40, the host ECU 16 and the method thereof disclosed in the present disclosure may be accomplished by one or more dedicated computer where a processor and a memory programmed to execute one or more functions, and a processor configured of one or more hardware logic circuits are combined. Furthermore, the computer programs may be stored, as instruction codes executed by the computer, into a computer readable non-transitory tangible recording media.

In other words, a method or a function provided by the processor and the like may be provided by software stored in a substantial recording media and a computer that executes the software, only the software, only the hardware and combination thereof. For example, a part of or all of functions included in the processor may be accomplished by a hardware. Embodiments for achieving a function with a hardware includes an embodiment where one or more ICs achieve the function.

The processor may be accomplished by CPU, MPU, GPU or DFP. The DFP is an abbreviation of data flow processor. The processor may be accomplished by a combination of a plurality of types of processors such as CPU, MPU and GPU. The processor may be accomplished by a system on chip (SoC).

Moreover, portions that execute various processes as described in the above embodiments may be accomplished by a hardware such as FPGA (field programable gate array), ASIC (application specific integrated circuit). The various programs may be stored in a non-transitory substantial recording media. As a recording media to which the programs are stored, various recording media such as HDD (hard disk drive), SSD (solid state drive), flash memory and SD (secure digital) card can be utilized.

The present disclosure includes the following configurations in addition to the configurations recited in the claims.

[1]

A control apparatus performing wireless communication with a supervisory apparatus (40) that acquires battery information indicating a battery state and transmits the acquired battery information, and controlling the supervisory apparatus based on the battery information, the control apparatus comprising:
a wireless communication unit (54) that wirelessly transmits to the supervisory apparatus a plurality of commands which are combined, corresponding to a control period set for a control of monitoring the battery state.
   [2]

The control apparatus according to [1],

wherein
a communication period for transmitting the battery information between the wireless communication unit and the supervisory apparatus is set shorter than the control period.
   [3]

The control apparatus according to [1] or [2],

wherein
the wireless communication unit transmits next and subsequent commands to the supervisory apparatus after receiving responses from all of the supervisory apparatuses, the responses corresponding to the transmitted commands which are combined.
   [4]
   The control apparatus according to any one of [1] to [3],
   wherein
a reception information determination unit is provided to determine whether responses corresponding to the transmitted commands which are combined, are received from all of the supervisory apparatuses and whether battery information corresponding to the commands are received.
   [5]

A supervisory apparatus that communicates with the control apparatus according to [1] to [4],

wherein
the supervisory apparatus performs a diagnosis of the battery based on battery information including information indicating the battery state and transmit the battery information and a diagnosis result of the battery to the control apparatus; and
the supervisory apparatus retransmits the battery information and the diagnosis result when failure occurs of wireless communication with the control apparatus.
   [6]

A supervisory apparatus that communicates with the control apparatus according to any one of [1] to [4],

wherein
the supervisory apparatus performs a diagnosis of the battery based on the battery information and transmits the battery information and a diagnosis result of the battery to the control apparatus; and
the supervisory apparatus retransmits battery information not including voltage information of the battery, when failing a wireless communication with the control apparatus.
   [7]

A supervisory apparatus that communicates with the control apparatus according to any one of [1] to [4],

wherein
the supervisory apparatus is provided with a memory unit (44c, 46a) that stores the battery information including voltage information of the battery; and
the supervisory apparatus removes voltage information of the battery information from the memory unit in response to failure of wireless communication with the control apparatus.
   [8]

A supervisory apparatus that communicates with the control apparatus according to any one of [1] to [4],

wherein
the supervisory apparatus transmits the battery information and information related to a command received from the control apparatus.
   [9]

A supervisory apparatus that communicates with the control apparatus according to any one of [1] to [4],
the supervisory apparatus comprising:
a supervisory unit (44a) that acquires battery information;
a conversion unit (44b) that converts an analog value of the battery information into a digital value and outputs the digital value;
a memory unit (44c) that stores the digital value of the battery information; and
a wireless communication unit (46) that wirelessly communicates with the control apparatus,
   wherein
the wireless communication unit (46) of the supervisor apparatus integrates a command for causing the memory unit to output the battery information externally and the battery information acquired based on the command for causing the memory unit to output the battery information externally, into the same communication frame, and transmits the communication frame to the wireless communication unit (54) of the control apparatus.
   [10]

The control apparatus according to any one of [1] to [4],

wherein
the control apparatus is provided with a sequence determination unit (54b) that determines, when receiving the battery information and the command from the supervisory apparatus, whether the battery information and the command are correctly received based on sequence information indicating a sequence with which the battery information and the command are to be received.
   [11]

A method comprising:
causing a control apparatus to control with a wireless communication, among a plurality of supervisory apparatuses (40) each acquiring battery information including information of a battery state and transmitting the acquired battery information, each supervisory apparatus based on the battery information; and
causing the control apparatus to cause a wireless communication unit (54) to wirelessly transmit a plurality of commands being integrated, corresponding to a control period which is set for monitoring the battery state.
   [12]

A program causing a control apparatus to execute a control for a plurality of supervisory apparatuses (40) each acquiring battery information including information of a battery state and transmitting the acquired battery information, the control apparatus controlling, based on the battery information, each of the supervisory apparatuses with a wireless communication,

wherein
the program causes the supervisory apparatus to cause a wireless communication unit (54) to wirelessly transmit a plurality of commands being integrated, corresponding to a control period which is set for monitoring the battery state.

The present disclosure has been described in accordance with the embodiments. However, the present disclosure is not limited to the embodiments and structure thereof. The present disclosure includes various modification examples and modifications within the equivalent configurations. Further, various combinations and modes and other combinations and modes including one element or more or less elements of those various combinations are within the range and technical scope of the present disclosure.

### Conclusion

The present disclosure provides a control apparatus, a supervisory apparatus, a control method and a program thereof capable of controlling a monitor of a state of the battery at each control period.

The wireless communication unit of the control apparatus according to a first aspect of the present disclosure acquires battery information including information indicating the battery state, wirelessly communicates with a supervisory apparatus which transmits the battery information, thereby controlling the supervisory apparatus based on the battery information. The control apparatus wirelessly transmits a plurality of commands being integrated, corresponding to a control period set for monitoring the battery state.

Thus, the control apparatus is able to communicate to acquire the battery information acquired by the battery supervisory apparatus at a suitable timing. Further, a plurality of commands are integrated and transmitted at the same time in accordance with a control period used for controlling the functions related to the battery supervisory processes. Hence, the control apparatus is able to issue commands for monitoring the battery state at every control period.

What is claimed is:

1. A control apparatus performing wireless communication with a supervisory apparatus that acquires battery information indicating a battery state and transmits the acquired battery information, and controlling the supervisory apparatus based on the battery information, the control apparatus comprising:
a wireless communication unit that wirelessly transmits a plurality of commands which are combined to the supervisory apparatus corresponding to a control period set for a control of monitoring the battery state.

2. The control apparatus according to claim 1,
wherein
a communication period for transmitting the battery information between the wireless communication unit and the supervisory apparatus is set shorter than the control period.

3. The control apparatus according to claim 1,
wherein
the wireless communication unit transmits next and subsequent commands to the supervisory apparatus after receiving responses from all of the supervisory apparatuses, the responses corresponding to the transmitted commands which are combined.

4. The control apparatus according to claim 1,
wherein
a reception information determination unit is provided to determine whether responses corresponding to the transmitted commands which are combined, are received from all of the supervisory apparatuses and whether battery information corresponding to the commands are received.

5. A supervisory apparatus that communicates with the control apparatus according to claim 1,
wherein
the supervisory apparatus is provided with a wireless communication unit that performs a diagnosis of the battery based on battery information including information indicating the battery state and transmit the battery information and a diagnosis result of the battery to the control apparatus; and
the wireless communication unit retransmits the battery information and the diagnosis result, in response to failure of wireless communication with the control apparatus.

6. A supervisory apparatus that communicates with the control apparatus according to claim 1,
wherein
the supervisory apparatus is provided with a wireless communication unit that transmits, when acquiring voltage information of the battery as battery information, the battery information including the voltage information to the control apparatus; and
the wireless communication unit retransmits battery information not including voltage information of the battery, in response to failure of wireless communication with the control apparatus.

7. A supervisory apparatus that communicates with the control apparatus according to claim 1,
wherein
the supervisory apparatus is provided with a memory unit that stores the battery information including voltage information of the battery; and
the supervisory apparatus removes voltage information of the battery information from the memory unit, in response to failure of wireless communication with the control apparatus.

8. A supervisory apparatus that communicates with the control apparatus according to claim 1,
wherein
the supervisory apparatus transmits the battery information and information related to a command received from the control apparatus.

9. A supervisory apparatus that communicates with the control apparatus according to claim 1,
the supervisory apparatus comprising:
a supervisory unit that acquires battery information;
a conversion unit that converts an analog value of the battery information into a digital value and outputs the digital value;
a memory unit that stores the digital value of the battery information; and
a wireless communication unit that wirelessly communicates with the control apparatus,
wherein
the wireless communication unit of the supervisor apparatus integrates a command for causing the memory unit to output the battery information externally and the battery information acquired based on the command for causing the memory unit to output the battery information externally, into the same communication frame, and transmits the communication frame to the wireless communication unit of the control apparatus.

10. The control apparatus according to claim 1,
wherein
the control apparatus is provided with a sequence determination unit that determines, when receiving the battery information and the command from the supervisory apparatus, whether the battery information and the command are correctly received based on sequence information indicating a sequence with which the battery information and the command are to be received.

11. A method comprising:
causing a control apparatus to control with a wireless communication, among a plurality of supervisory apparatuses each acquiring battery information including information of a battery state and transmitting the acquired battery information, each supervisory apparatus based on the battery information; and
causing the control apparatus to cause a wireless communication unit to wirelessly transmit a plurality of commands being integrated, corresponding to a control period which is set for monitoring the battery state.

12. A program causing a control apparatus to execute a control for a plurality of supervisory apparatuses each acquiring battery information including information of a battery state and transmitting the acquired battery information, the control apparatus controlling, based on the battery information, each of the supervisory apparatuses with wireless communication,
wherein
the program causes the supervisory apparatus to cause a wireless communication unit to wirelessly transmit a plurality of commands being integrated, corresponding to a control period which is set for monitoring the battery state.
